(19) United States
(12) Patent Application Publication
(10) Pub. No.: US 2026/0190726 A1
(43) Pub. Date: Jul. 2, 2026

(54) DISPLAY PANEL AND ELECTRONIC DEVICE INCLUDING THE SAME

(71) Applicant: Samsung Display Co., LTD., Yongin-si (KR)

(72) Inventors: Sunhwa Lee, Yongin-si (KR); Jihoon Yang, Yongin-si (KR); Soil Yoon, Yongin-si (KR); Seungjun Lee, Yongin-si (KR)

(21) Appl. No.: 19/428,883

(22) Filed: Dec. 22, 2025

(30) Foreign Application Priority Data
Dec. 26, 2024 (KR) 10-2024-0197377

(51) Int. Cl. H10K 59/131; H10H 29/49; H10K 102/00

(52) U.S. Cl. CPC H10K 59/1315; H10H 29/49; H10K 2102/311

(57) ABSTRACT

A driving circuit includes a plurality of stages. The plurality of stages are arranged in a plurality of island portions, at least one signal line connected to the stages may include at least one first conductive line disposed in first directional bridge portions and at least one second conductive line disposed in second directional bridge portions, and the at least one second conductive line may extend across the plurality of island portions.

### BACKGROUND

### 1. Field

Embodiments of the disclosure relate to a display device, and more particularly, to a stretchable display device and an electronic device including the same.

### 2. Description of the Related Art

As display devices that visually display electrical signals have been developed, various display devices having excellent characteristics, such as thinness, light weight, and low power consumption, have been introduced. For example, flexible display devices that may be folded or rolled up have been introduced. Recently, research and development on stretchable display devices that may be changed into various shapes have been actively conducted.

### SUMMARY

Embodiments of the disclosure may provide a display device having improved display quality. However, this objective is merely illustrative, and the scope of the disclosure is not limited thereto.

A display panel in an embodiment of the disclosure includes a non-display area having defined therein a plurality of island portions and a plurality of bridge portions extending to the plurality of island portions to each other, wherein a driving circuit including a plurality of stages is in the non-display area, at least one stage among the plurality of stages is disposed in each of the plurality of island portions, at least one signal line connected to the plurality of stages is disposed in the plurality of bridge portions, the plurality of bridge portions include first directional bridge portions and second directional bridge portions, the first directional bridge portions extending in a first direction, and the second directional bridge portions extending in a second direction perpendicular to the first direction, the plurality of stages are arranged in the plurality of island portions disposed in the second direction, the at least one signal line includes at least one first conductive line and at least one second conductive line, the at least one first conductive line being disposed in the first directional bridge portions, and the at least one second conductive line being disposed in the second directional bridge portions, and the at least one second conductive line extends across the plurality of island portions.

In an embodiment, the at least one first conductive line may include an output line configured to output an output signal of the at least one stage.

In an embodiment, the at least one second conductive line may include a voltage line and a clock line, the voltage line being configured to transmit a voltage to the at least one stage, and the clock signal being configured to transmit a clock signal to the at least one stage.

In an embodiment, the voltage line and the clock line may be disposed in different layers.

In an embodiment, one of the plurality of stages may be disposed in each of the plurality of island portions.

In an embodiment, an odd-numbered stage and an even-numbered stage of the plurality of stages may be disposed in each of the plurality of island portions.

A display panel in an embodiment of the disclosure includes a non-display area having defined therein a plurality of island portions and a plurality of bridge portions extending to the plurality of island portions to each other, wherein the display panel comprises: a first driving circuit including a plurality of first stages in the non-display area; and a second driving circuit including a plurality of second stages in the non-display area, wherein the first driving circuit is closer to a display area than the second driving circuit is to the display area. The plurality of island portions include first island portions of a first column and second island portions of a second column, the first island portions having disposed therein the plurality of first stages, and the second island portions having disposed therein the plurality of second stages, the plurality of bridge portions include first area bridge portions and second area bridge portions, the first area bridge portions having disposed therein at least one first signal line connected to the plurality of first stages, and the second area bridge portions having disposed therein at least one second signal line connected to the plurality of second stages, the first area bridge portions include first horizontal bridge portions and first vertical bridge portions, the first horizontal bridge portions extending in a first direction, and the first vertical bridge portions extending in a second direction perpendicular to the first direction, the second area bridge portions include second horizontal bridge portions and second vertical bridge portions, the second horizontal bridge portions extending in the first direction, and the second vertical bridge portions extending in the second direction, the at least one first signal line includes at least one first horizontal conductive line and at least one first vertical conductive line, the at least one first horizontal conductive line being disposed in the first horizontal bridge portions, and the at least one first vertical conductive line being disposed in the first vertical bridge portions, the at least one second signal line includes at least one second horizontal conductive line and at least one second vertical conductive line, the at least one second horizontal conductive line being disposed in the second horizontal bridge portions, and the at least one second vertical conductive line being disposed in the second vertical bridge portions, the at least one first vertical conductive line extends across the first island portions, and the at least one second vertical conductive line extends across the second island portions.

In an embodiment, one of the plurality of first stages may be disposed in each of the first island portions, and an odd-numbered second stage and an even-numbered second stage of the plurality of second stages may be disposed in each of the second island portions.

In an embodiment, the first horizontal conductive line may include a first output line configured to output an output signal of the one of the plurality of first stages, and the second horizontal conductive line may include a second output line and a third output line, the second output line being configured to output an output signal of the odd-numbered second stage, and the third output line being configured to output an output signal of the even-numbered second stage.

In an embodiment, each of the first horizontal bridge portions may extend to one of the first island portions and one of the second island portions, which are arranged in a same row.

In an embodiment, the first output line may be disposed in a first horizontal bridge portion and a second horizontal bridge portion, the first horizontal bridge portion being disposed in a first row, and the second horizontal bridge portion being disposed in the first row and extending to a second island portion therein, the second output line and the third output line may be disposed apart from each other in the second horizontal bridge portion disposed in the first row, and in the second horizontal bridge portion disposed in the first row, the first output line may at least partially overlap the second output line and the third output line in a plan view.

In an embodiment, a connection electrode may be disposed in the second island portion disposed in the first row, and the connection electrode may connect the first output line disposed in the first horizontal bridge portion disposed in the first row to the first output line disposed in the second horizontal bridge portion disposed in the first row.

In an embodiment, the first output line disposed in the first horizontal bridge portion disposed in the first row and the first output line disposed in the second horizontal bridge portion disposed in the first row may be disposed in different layers.

In an embodiment, the first vertical conductive line may include a first voltage line and a first clock line, the first voltage line being configured to transmit a voltage to the one of the plurality of first stages, and the first clock line being configured to transmit a clock signal to the one of the plurality of first stages, and the second vertical conductive line may include a second voltage line and a second clock line, the second voltage line being configured to transmit a voltage to the odd-numbered second stage and the even-numbered second stage, and the second clock line being configured to transmit a clock signal to the odd-numbered second stage and the even-numbered second stage.

In an embodiment, the first voltage line and the first clock line may be disposed in different layers, the second voltage line may be disposed in a same layer as the first voltage line, and the second clock line may be disposed in a same layer as the first clock line.

In an embodiment, the first vertical conductive line may further include a first carry line configured to transmit a start signal to the one of the plurality of first stages, and the second vertical conductive line may further include a second carry line configured to transmit a start signal to the odd-numbered second stage.

In an embodiment, the first carry line may be disposed in a different layer from the first voltage line, the first voltage line may overlap the first carry line, and the second carry line may be disposed in a same layer as the second voltage line.

An electronic device in an embodiment of the disclosure includes: a display panel having defined therein a display area and a non-display area outside the display area, the display area having disposed therein a plurality of pixels; and a driving circuit disposed in the non-display area and configured to output a gate signal to the plurality of pixels of the display panel. The non-display area has defined therein a plurality of island portions and a plurality of bridge portions extending to the plurality of island portions to each other. The driving circuit includes: a first driving circuit including a plurality of first stages; and a second driving circuit including a plurality of second stages, wherein the first driving circuit is closer to the display area than the second driving circuit is to the display area. The plurality of island portions include first island portions of a first column and second island portions of a second column, the first island portions having disposed therein the plurality of first stages, and the second island portions having disposed therein the plurality of second stages, the plurality of bridge portions include first area bridge portions and second area bridge portions, the first area bridge portions having disposed therein at least one first signal line connected to the plurality of first stages, and the second area bridge portions having disposed therein at least one second signal line connected to the plurality of second stages, the first area bridge portions include first horizontal bridge portions and first vertical bridge portions, the first horizontal bridge portions extending in a first direction, and the first vertical bridge portions extending in a second direction perpendicular to the first direction, the second area bridge portions include second horizontal bridge portions and second vertical bridge portions, the second horizontal bridge portions extending in the first direction, and the second vertical bridge portions extending in the second direction, the at least one first signal line includes at least one first horizontal conductive line and at least one first vertical conductive line, the at least one first horizontal conductive line being disposed in the first horizontal bridge portions, and the at least one first vertical conductive line being disposed in the first vertical bridge portions, the at least one second signal line includes at least one second horizontal conductive line and at least one second vertical conductive line, the at least one second horizontal conductive line being disposed in the second horizontal bridge portions, and the at least one second vertical conductive line being disposed in the second vertical bridge portions, the at least one first vertical conductive line extends across the first island portions, and the at least one second vertical conductive line extends across the second island portions.

In an embodiment, one of the plurality of first stages may be disposed in each of the first island portions, and an odd-numbered second stage and an even-numbered second stage of the plurality of second stages may be disposed in each of the second island portions.

In an embodiment, the first vertical conductive line may include a first voltage line, a first clock line, and a first carry line, the first voltage line being configured to transmit a voltage to the one of the plurality of first stages, the first clock line being configured to transmit a clock signal to the one of the plurality of first stages, and the first carry line being configured to transmit a start signal to the one of the plurality of first stages, and the second vertical conductive line may include a second voltage line, a second clock line, and a second carry line, the second voltage line being configured to transmit a voltage to the odd-numbered second stage and the even-numbered second stage, the second clock line being configured to transmit a clock signal to the odd-numbered second stage and the even-numbered second stage, and the second carry line being configured to transmit a start signal to the odd-numbered second stage. The first voltage line and the first clock line may be disposed in different layers, the second voltage line may be disposed in a same layer as the first voltage line, the second clock line may be disposed in a same layer as the first clock line, the first carry line may be disposed in a different layer from the first voltage line, and the second carry line may be disposed in a same layer as the second voltage line.

By embodiments of the disclosure, a display device having improved display quality may be provided. However, the scope of the disclosure is not limited by this effect.

### BRIEF DESCRIPTION OF DRAWINGS

The above and other embodiments, advantages and features of this disclosure will become more apparent by describing in further detail embodiments thereof with reference to the accompanying drawings.

FIG. 1 is a schematic perspective view of an embodiment of a display panel 1 according to the disclosure.

FIGS. 2A and 2B are perspective views of a state in which the display panel 1 of FIG. 1 is stretched in a first direction.

FIG. 2C is a perspective view of a state in which the display panel 1 of FIG. 1 is stretched in a second direction.

FIG. 2D is a perspective view of a state in which the display panel 1 of FIG. 1 is stretched in the first direction and the second direction.

FIG. 2E is a perspective view of a state in which the display panel 1 of FIG. 1 is stretched in a third direction.

FIG. 3 is a schematic plan view of an embodiment of the display panel 1.

FIG. 4 is an enlarged plan view of region IV of FIG. 3 as an embodiment of a portion of the display panel 1.

FIG. 5A is a schematic cross-sectional view of an embodiment of a first island portion and a first bridge portion that are arranged in a display area.

FIG. 5B is a schematic cross-sectional view of an embodiment of a second island portion and a second bridge portion that are arranged in a non-display area.

FIGS. 6A and 6B are equivalent circuit diagrams of an embodiment of a pixel.

FIG. 7A is a schematic cross-sectional view of an embodiment of a light-emitting element of a display panel.

FIG. 7B is a schematic cross-sectional view of an embodiment of a light-emitting element of a display panel.

FIG. 8 is a schematic view of an embodiment of a display panel.

FIG. 9 is a schematic view of an embodiment of a gate driving circuit.

FIG. 10 is a schematic view of an embodiment of arbitrary stages constituting a gate driving circuit.

FIG. 11 is a schematic view of an embodiment of an arbitrary stage of a first driving circuit 131 or a second driving circuit 133.

FIG. 12 is a schematic view of an embodiment of an arbitrary stage of a third driving circuit 135.

FIG. 13 is a schematic view of an embodiment of an arbitrary stage of a fourth driving circuit 137.

FIG. 14 is a schematic plan view of an embodiment of a portion of a gate driving circuit 130.

FIG. 15 is a schematic view of an embodiment of a portion of the fourth driving circuit 137.

FIGS. 16 to 19 are schematic views of components of each layer of the fourth driving circuit 137 shown in FIG. 15.

FIG. 20 is a cross-sectional view of the fourth driving circuit 137 shown in FIG. 15, taken along lines Ia-Ia′, IIa-IIa′, and IIIa-IIIa′.

FIG. 21 is a schematic view of an embodiment of a portion of the third driving circuit 135.

FIGS. 22 to 25 are schematic views of components of each layer of the third driving circuit 135 shown in FIG. 21.

FIG. 26 is a cross-sectional view of the third driving circuit 135 shown in FIG. 21, taken along lines Ib-Ib′, IIb-IIb′, and IIIb-IIIb′.

FIG. 27 is a schematic view of an embodiment of a portion of the second driving circuit 133.

FIGS. 28 to 31 are schematic views of components of each layer of the second driving circuit 133 shown in FIG. 27.

FIG. 32 is a cross-sectional view of the second driving circuit 133 shown in FIG. 27, taken along lines Ic-Ic′, IIc-IIc′, and IIIc-IIIc′.

FIG. 33 is a schematic view of an embodiment of a portion of the first driving circuit 131.

FIGS. 34 to 37 are schematic views of components of each layer of the first driving circuit 131 shown in FIG. 33.

FIG. 38 is a cross-sectional view of the first driving circuit 131 shown in FIG. 33, taken along lines Id-Id′, IId-IId′, and IIId-IIId′.

FIG. 39 is a schematic view of an embodiment of a fourth conductive layer.

FIG. 40 is a schematic view of an embodiment of a fifth conductive layer.

FIG. 41 is a schematic perspective view of an embodiment of an electronic device including a display panel.

FIG. 42 is a block diagram of an embodiment of an electronic device.

FIGS. 43A to 43I are schematic perspective views of embodiments of an electronic device including a display panel, according to the disclosure.

### DETAILED DESCRIPTION

As the disclosure allows for various modifications and numerous embodiments, particular embodiments will be illustrated in the drawings and described in detail in the detailed description. Effects and features of the disclosure and methods of achieving the same will become apparent by referring to embodiments described below in detail with reference to the drawings. However, the disclosure is not limited to the embodiments disclosed below and may be implemented in various forms.

In the following embodiments, terms such as “first” and “second” are not used in a limiting sense, but are used for the purpose of distinguishing one component from another component.

In the following embodiments, singular expressions include plural expressions unless the context clearly indicates otherwise.

In the following embodiments, terms such as “include” or “have” specify the presence of features or components described in the specification, and do not preclude the possibility of addition of one or more other features or components.

In the following embodiments, reference to a portion, such as a layer, a region, or a component, being on or above another portion includes not only the case where the portion is directly on the other portion, but also the case where intervening layers, regions, or components are present.

In the specification, “A and/or B” refers to the case of A, B, or A and B. Also, in the specification, “at least one of A and B” refers to the case of A, B, or A and B.

In the following embodiments, reference to X and Y being connected may include the case where X and Y are electrically connected, the case where X and Y are functionally connected, and the case where X and Y are directly connected. Here, X and Y may be objects (e.g., devices, elements, circuits, wirings, electrodes, terminals, conductive layers, layers, etc.). Therefore, the disclosure is not limited to a predetermined connection relationship, e.g., a connection relationship indicated in the drawings or the detailed description, and may include connection relationships other than those indicated in the drawings or the detailed description.

The case where X and Y are electrically connected may include, e.g., the case where at least one element (e.g., a switch, a transistor, a capacitance element, an inductor, a resistance element, a diode, etc.) that enables electrical connection of X and Y is connected between X and Y.

In the following embodiments, “ON” used in association with a state of an element may refer to an activated state of the element, and “OFF” may refer to a deactivated state of the element. “ON” used in association with a signal received by the element may refer to a signal activating the element, and “OFF” may refer to a signal deactivating the element. The element may be activated by a high-level voltage or a low-level voltage. In a n embodiment, a P-channel transistor (a P-type transistor) is activated by a low-level voltage, and an N-channel transistor (an N-type transistor) is activated by a high-level voltage. Therefore, it should be understood that “ON” voltages for a P-type transistor and an N-type transistor are opposite (low versus high) voltage levels.

In the following embodiments, the x-direction, the y-direction, and the z-direction are not limited to directions along three axes of the quadrangular, e.g., rectangular coordinate system, and may be interpreted in a broader sense. In an embodiment, the x-direction, the y-direction, and the z-direction may be perpendicular to each other, or may refer to different directions that are not perpendicular to each other.

In the specification, when an illustrative embodiment may be implemented differently, a predetermined process order may be performed differently from the described order. In an embodiment, two processes described in succession may be performed substantially simultaneously, or may be performed in an order opposite to the described order.

Sizes of components in the drawings may be exaggerated or reduced for convenience of description. In an embodiment, sizes and thicknesses of components in the drawings are arbitrarily illustrated for convenience of description, and thus, the disclosure is not necessarily limited to the illustrations.

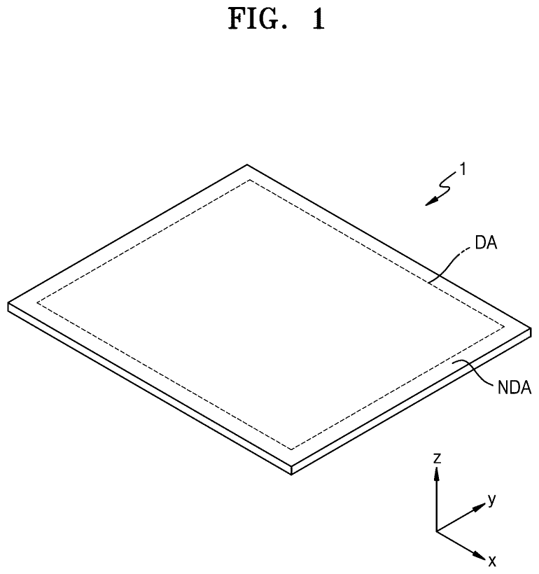

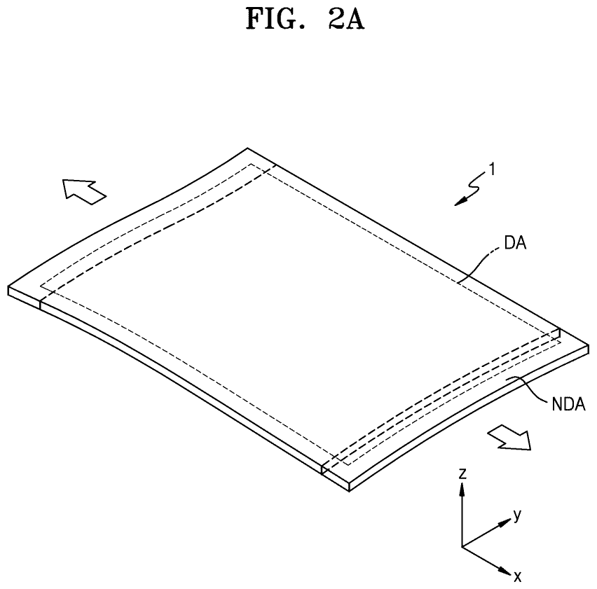

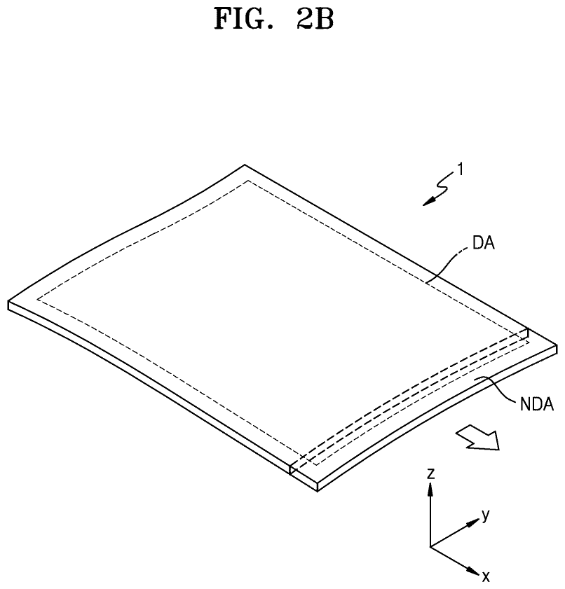

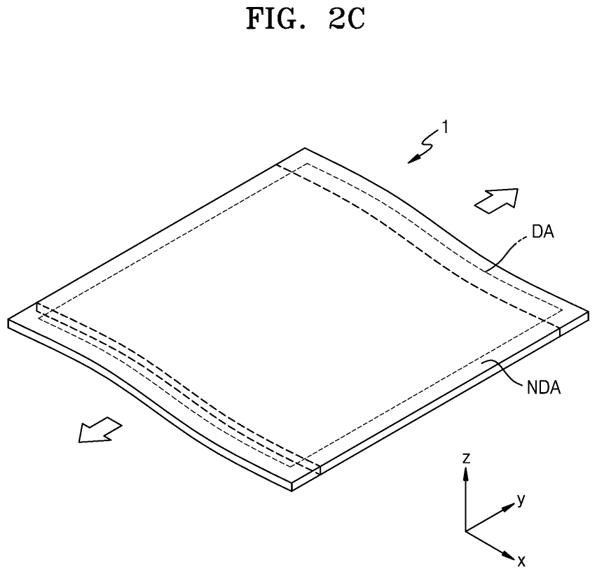

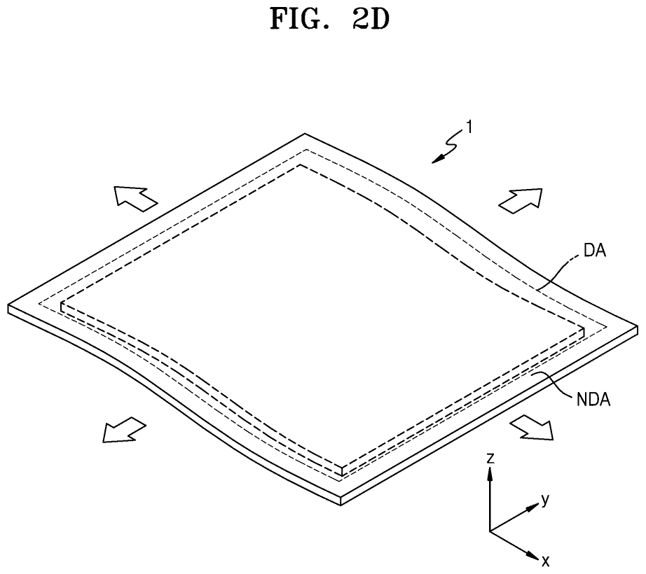

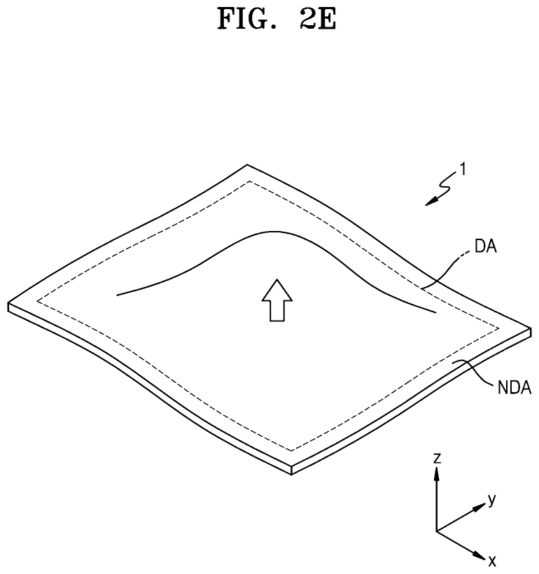

FIG. 1 is a schematic perspective view of an embodiment of a display panel 1 according to the disclosure. FIGS. 2A and 2B are perspective views of a state in which the display panel 1 of FIG. 1 is stretched in a first direction. FIG. 2C is a perspective view of a state in which the display panel 1 of FIG. 1 is stretched in a second direction. FIG. 2D is a perspective view of a state in which the display panel 1 of FIG. 1 is stretched in the first direction and the second direction. FIG. 2E is a perspective view of a state in which the display panel 1 of FIG. 1 is stretched in a third direction.

Referring to FIG. 1, the display panel 1 may be a display panel of a stretchable display device that may be stretched or shrunk in various directions. The display panel 1 may include a display area DA and a non-display area NDA. The display area DA may include a plurality of pixels. The display panel 1 may provide a predetermined image by light emitted from the plurality of pixels. The non-display area NDA may be disposed outside the display area DA. The non-display area NDA may surround an entirety of the display area DA.

The display panel 1 may be stretched in a first direction (e.g., an x-direction and/or a −x-direction) due to an external force applied by an external object or a user. In an embodiment, as shown in FIGS. 2A and 2B, the display area DA and/or the non-display area NDA of the display panel 1 may be stretched in the first direction (e.g., the x-direction and/or the −x-direction). In an embodiment, the display panel 1 may be stretched in the x-direction and the −x-direction, as shown in FIG. 2A, or may be stretched in the x-direction or the −x-direction while one side of the display panel 1 is fixed. FIG. 2B shows an embodiment in which the display panel 1 is stretched in the x-direction while one side thereof is fixed.

The display panel 1 may be stretched in a second direction (e.g., a y-direction and/or a −y-direction) due to an external force applied by an external object or a user. In an embodiment, as shown in FIG. 2C, the display area DA and/or the non-display area NDA of the display panel 1 may be stretched in the y-direction and the −y-direction. In another embodiment, the display panel 1 may be stretched in the y-direction or the −y-direction while one side thereof is fixed.

The display panel 1 may be stretched in a plurality of directions, e.g., in the first direction (e.g., the x-direction and/or the −x-direction) and the second direction (e.g., the y-direction and/or the −y-direction), due to an external force applied by an external object or a part of the human body. As shown in FIG. 2D, the display area DA and/or the non-display area NDA of the display panel 1 may be stretched in the ±x-direction and the ±y-direction.

The display panel 1 may be stretched in a third direction (e.g., a z-direction or a −z-direction) due to an external force applied by an external object or a part of the human body. In an embodiment, FIG. 2E shows that a portion of the display panel 1, e.g., a portion of the display area DA, protrudes in the z-direction. In another embodiment, a portion of the display panel 1, e.g., a portion of the display area DA, may protrude in the −z-direction (or be recessed in the z-direction).

FIGS. 2A to 2E show that the display panel 1 is stretched in the first direction, the second direction, and/or the third direction, but the disclosure is not limited thereto. In another embodiment, the display panel 1 may be variously deformed into an irregular shape, e.g., may be bent or twisted along two or more axes.

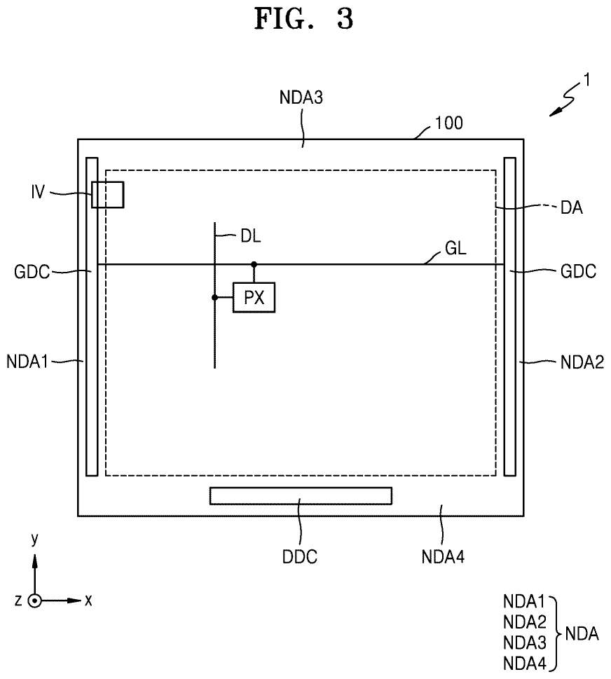

FIG. 3 is a schematic plan view of an embodiment of the display panel 1.

The display panel 1 may include a substrate 100. A plurality of pixels PX may be disposed in the display area DA of the substrate 100. Each pixel PX may include a pixel circuit and a light-emitting element electrically connected to the pixel circuit. The pixel circuit may include a plurality of transistors and at least one capacitor, and may be a pixel driving circuit that controls driving of the light-emitting element. Each pixel PX may be connected to a gate line GL and a data line DL.

In the non-display area NDA surrounding the display area DA, a driving circuit for providing electrical signals to the light-emitting elements disposed in the display area DA and the pixel circuits electrically connected to the light-emitting elements may be disposed. A gate driving circuit GDC may be disposed in each of a first non-display area NDA1 and a second non-display area NDA2, which are arranged on two sides of the display area DA. The gate driving circuit GDC may be connected to the gate lines GL disposed in the display area DA. FIG. 3 shows that the gate driving circuit GDC is disposed in each of the first non-display area NDA1 and the second non-display area NDA2, but the disclosure is not limited thereto. In another embodiment, the gate driving circuit GDC may be disposed in any one of the first non-display area NDA1 and the second non-display area NDA2. A portion or all of the gate driving circuit GDC may be directly formed in the non-display area NDA during a process of forming a transistor constituting the pixel circuit in the display area DA.

A data driving circuit DDC may be disposed in a third non-display area NDA3 and/or a fourth non-display area NDA4 extending to the first non-display area NDA1 and the second non-display area NDA2. In an embodiment, FIG. 3 shows that the data driving circuit DDC is disposed in the fourth non-display area NDA4. In another embodiment, the data driving circuit DDC may be disposed in each of the third non-display area NDA3 and the fourth non-display area NDA4.

The data driving circuit DDC may be formed as an integrated circuit chip. In an embodiment, the data driving circuit DDC may be directly disposed in the fourth non-display area NDA4 of the substrate 100 in a chip-on-glass (“COG”) or chip-on-plastic (“COP”) manner, as shown in FIG. 3. In another embodiment, the display panel 1 may further include a flexible circuit board (not shown) electrically connected thereto through a terminal portion (not shown) disposed in the fourth non-display area NDA4 of the substrate 100, and the data driving circuit DDC may be disposed on the flexible circuit board.

The elongation of the non-display area NDA may be equal to or less than the elongation of the display area DA. In an embodiment, the non-display area NDA may have a different elongation for each area. In an embodiment, the first non-display area NDA1, the second non-display area NDA2, and the third non-display area NDA3 may have substantially the same elongation, but the fourth non-display area NDA4 may have an elongation less than the elongation of each of the first non-display area NDA1, the second non-display area NDA2, and the third non-display area NDA3. In the specification, the term “elongation” refers to a numerical value representing a change in length (ΔL/L) by which the display panel 1 may be stretched without physical damage to the display panel 1 when an external force is applied to the display panel 1. Here, ΔL represents an amount of change in the length of the display panel, and L represents the initial length of the display panel.

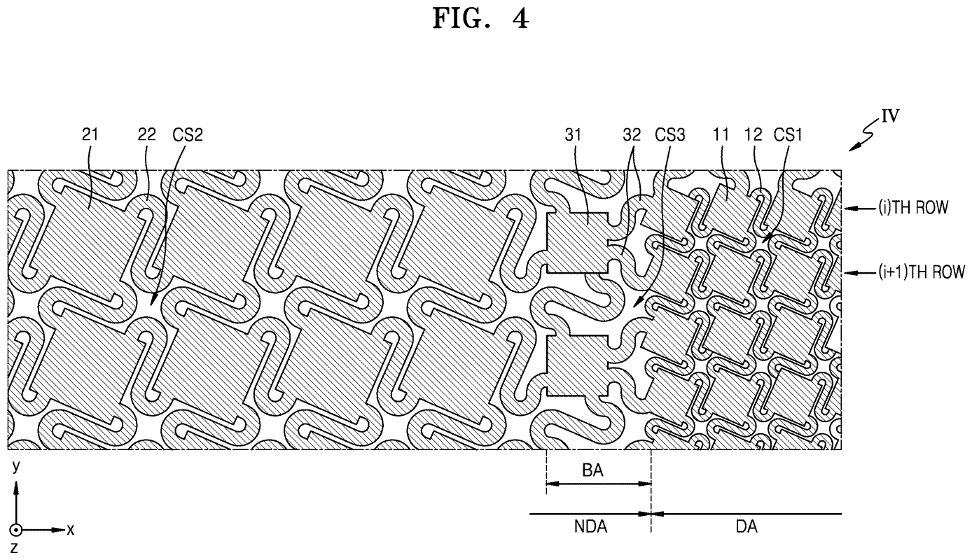

FIG. 4 is an enlarged plan view of region IV of FIG. 3 in an embodiment of a portion of the display panel 1.

Referring to FIG. 4, the display panel 1 may include first island portions 11 apart from each other in the first direction (e.g., the x-direction or the −x-direction) and the second direction (e.g., the y-direction or the −y-direction) in the display area DA, and first bridge portions 12 extending to neighboring (adjacent) ones of the first island portions 11.

In an embodiment, at least one of sides of the first island portion 11 may be inclined at a predetermined angle with respect to the first direction (e.g., the x-direction or the −x-direction) and/or the second direction (e.g., the y-direction or the −y-direction). In an embodiment, the first island portion 11 may include four sides, and each of the four sides may extend in a direction oblique to the first direction and/or the second direction.

The first island portion 11 may extend to a plurality of first bridge portions 12. In an embodiment, the first island portion 11 may extend to four first bridge portions 12. The four first bridge portions 12 may be respectively connected to the four sides of the first island portion 11. Two first bridge portions 12 may be respectively connected to two sides of the first island portion 11 that are disposed opposite to each other in the first direction (e.g., the x-direction or the −x-direction), and the remaining two first bridge portions 12 may be respectively connected to the remaining two sides of the first island portion 11 that are disposed opposite to each other in the second direction (e.g., the y-direction or the −y-direction).

The display panel 1 may include second island portions 21 apart from each other in the first direction (e.g., the x-direction or the −x-direction) and the second direction (e.g., the y-direction or the −y-direction), and second bridge portions 22 extending to neighboring (adjacent) ones of the second island portions 21, in a non-display area, e.g., the first non-display area NDA1 shown in FIG. 3.

In an embodiment, at least one of sides of the second island portion 21 may be inclined at a predetermined angle with respect to the first direction (e.g., the x-direction or the −x-direction) and/or the second direction (e.g., the y-direction or the −y-direction). In an embodiment, the second island portion 21 may include four sides, and each of the four sides may extend in a direction oblique to the first direction and/or the second direction.

The second island portion 21 may extend to a plurality of second bridge portions 22. In an embodiment, the second island portion 21 may extend to four second bridge portions 22. The four second bridge portions 22 may be respectively connected to the four sides of the second island portion 21. Two second bridge portions 22 may be respectively connected to two sides of the second island portion 21 that are disposed opposite to each other in the first direction (e.g., the x-direction or the −x-direction), and the remaining two second bridge portions 22 may be respectively connected to the remaining two sides of the second island portion 21 that are disposed opposite to each other in the second direction (e.g., the y-direction or the −y-direction). The second bridge portions 22 may be arranged apart from each other by a second opening CS2 disposed between the second bridge portions 22.

The second island portions 21 of any one row arranged in the first non-display area NDA1 may correspond to the first island portions 11 of at least one row arranged in the display area DA. In an embodiment, the second island portions 21 of any one row arranged in the first non-display area NDA1 may correspond to the first island portions 11 arranged in k rows (where k is a positive number greater than or equal to 2). FIG. 4 shows an embodiment in which the second island portions 21 of any one row arranged in the first non-display area NDA1 correspond to the first island portions 11 arranged in an (i)th row and the first island portions 11 arranged in an (i+1)th row in the display area DA (where i is a positive number greater than 0).

In the first non-display area NDA1, third island portions 31 and third bridge portions 32 may be arranged in a boundary area BA next (adjacent) to the display area DA to connect the first island portion 11 of the display area DA to the second island portion 21 of the first non-display area NDA1. The third island portion 31 may extend to a plurality of third bridge portions 32. In an embodiment, the third island portion 31 may extend to five third bridge portions 32. One third bridge portion 32 may extend to one side of the second island portion 21 and one side of the third island portion 31 in the first direction. Two third bridge portions 32 may respectively extend to one side of the third island portion 31 and one side of the first island portion 11 in the first direction. Two third bridge portions 32 may be respectively connected to two sides of the third island portion 31 that are disposed opposite to each other in the second direction. The third bridge portions 32 may be arranged apart from each other by an opening CS3 disposed between the third bridge portions 32.

In an embodiment, the first island portion 11, the second island portion 21, and the third island portion 31 may have a polygonal shape, such as a quadrangle, a pentagon, or a hexagon, a circular shape, or an oval shape. The first bridge portion 12, the second bridge portion 22, and the third bridge portion 32 may have a straight shape or a winding shape, such as a serpentine shape, a sine wave shape, or a letter S shape.

In an embodiment, the size of the second island portion 21 may be greater than the size of the first island portion 11. The size of the third island portion 31 may be equal to the size of the first island portion 11 or greater than the size of the first island portion 11, and may be less than the size of the second island portion 21. The size and/or width of the second bridge portion 22 may be greater than the size and/or width of the first bridge portion 12. The size and/or width of the third bridge portion 32 may be equal to the size and/or width of the second bridge portion 22 or less than the size and/or width of the second bridge portion 22.

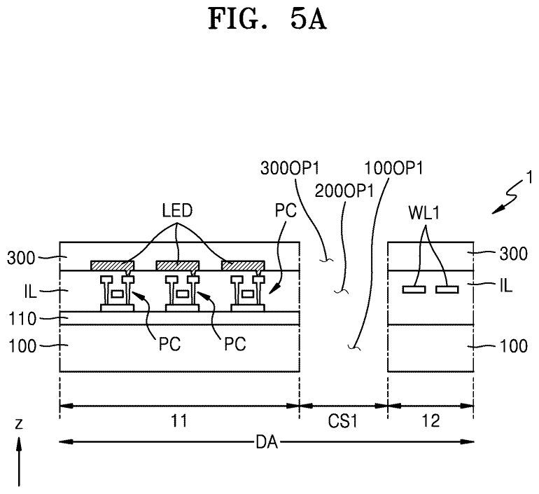

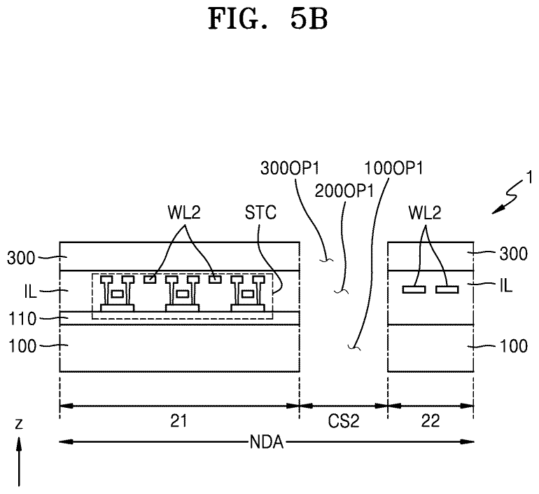

FIG. 5A is a schematic cross-sectional view of an embodiment of a first island portion and a first bridge portion that are arranged in a display area. FIG. 5B is a schematic cross-sectional view of an embodiment of a second island portion and a second bridge portion that are arranged in a non-display area.

A light-emitting element and a pixel circuit PC electrically connected thereto may be arranged in the first island portion 11. Conductive lines WL1 electrically connected to the pixel circuits PC arranged in neighboring (adjacent) ones of the first island portions 11 may be arranged in the first bridge portion 12. At least one stage circuit STC of a plurality of stages constituting the gate driving circuit GDC may be disposed in the second island portion 21. Conductive lines WL2 electrically connected to the stage circuits STC arranged in neighboring (adjacent) ones of the second island portions 21 may be arranged in the second bridge portion 22.

In the first island portion 11, a barrier layer 110 including an inorganic insulating material may be arranged on the substrate 100, and a pixel circuit PC and an insulating layer IL including an inorganic insulating material and/or an organic insulating material may be arranged on the barrier layer 110. A light-emitting element LED may be electrically connected to the pixel circuit PC corresponding thereto. In the second island portion 21, a barrier layer 110 including an inorganic insulating material may be disposed on the substrate 100, and a stage circuit STC and an insulating layer IL may be arranged on the barrier layer 110.

In the first bridge portion 12 and the second bridge portion 22, an insulating layer IL including an organic insulating material may be disposed on the substrate 100. When the display panel 1 is stretched, the first bridge portion 12 and the second bridge portion 22, which are subject relatively high deformation, may not have a layer including an inorganic insulating material that is prone to cracking, unlike the first island portion 11 and the second island portion 21.

In an embodiment, the substrate 100 corresponding to the first bridge portion 12 and the second bridge portion 22 may have the same stacked structure as the substrate 100 corresponding to the first island portion 11 and the second island portion 21. In an embodiment, the substrate 100 corresponding to the first bridge portion 12 and the second bridge portion 22 and the substrate 100 corresponding to the first island portion 11 and the second island portion 21 may be polymer resin layers that are formed together in the same process. In another embodiment, the substrate 100 corresponding to the first bridge portion 12 may have a stacked structure different from that of the substrate 100 corresponding to the first island portion 11 and the second island portion 21. In some embodiments, the substrate 100 corresponding to the first island portion 11 and the second island portion 21 may have a multi-layer structure including a base layer including polymer resin and a barrier layer including an inorganic insulating material, and the substrate 100 corresponding to the first bridge portion 12 and the second bridge portion 22 may have a structure including a polymer resin layer without a layer including an inorganic insulating material.

The conductive lines WL1 of the first bridge portion 12 may be signal lines (e.g., gate lines, data lines, driving voltage lines, initialization voltage lines, voltage connection lines, etc.) connected to the pixel circuit PC of the first island portion 11. The conductive lines WL2 of the second bridge portion 22 may be signal lines (e.g., clock lines, voltage lines, input lines, output lines, etc.) connected to the stage circuit STC of the second island portion 21. An encapsulation layer 300 may also be disposed in the first bridge portion 12 and the second bridge portion 22. In another embodiment, the encapsulation layer 300 may not be in the first bridge portion 12 and the second bridge portion 22.

The substrate 100, the barrier layer 110, the insulating layer IL, and the encapsulation layer 300 may each include an area corresponding to the first island portion 11 and the second island portion 21, an area corresponding to the first bridge portion 12 and the second bridge portion 22, and openings corresponding to the first opening CS1 and the second opening CS2. Each of an opening 100OP1 of the substrate 100, an opening 200OP1 of the barrier layer 110 and the insulating layer IL, and an opening 300OP1 of the encapsulation layer 300 may overlap the first opening CS1 and the second opening CS2, and may have a shape similar to those of the first opening CS1 and the second opening CS2.

The encapsulation layer 300 may be disposed on the light-emitting element LED and a stage. The encapsulation layer 300 may include an inorganic encapsulation layer and/or an organic encapsulation layer. In some embodiments, the encapsulation layer 300 may include a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material such as resin. In some embodiments, the encapsulation layer 300 may include urethane epoxy acrylate. The encapsulation layer 300 may include a photosensitive material such as photoresist.

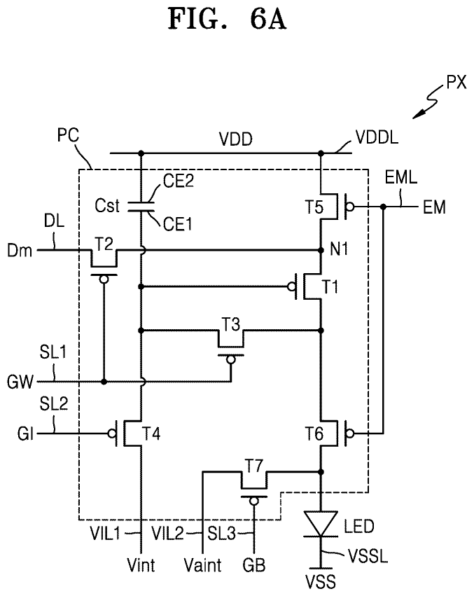

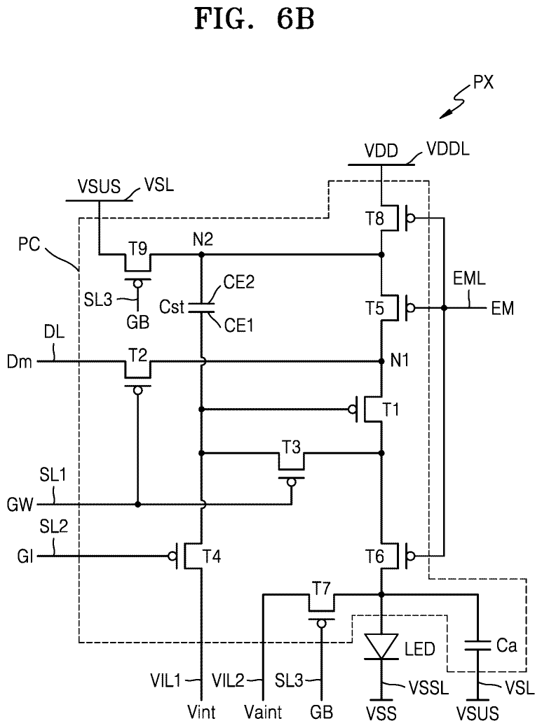

FIGS. 6A and 6B are equivalent circuit diagrams of an embodiment of a pixel.

Referring to FIG. 6A, the pixel PX may include a light-emitting element LED and a pixel circuit PC connected to the light-emitting element LED. The pixel circuit PC may include a first transistor T1, a second transistor T2, a third transistor T3, a fourth transistor T4, a fifth transistor T5, a sixth transistor T6, a seventh transistor T7, and a capacitor Cst.

The pixel circuit PC is electrically connected to signal lines and voltage lines. The signal lines may include gate lines, such as a first scan line SL1, a second scan line SL2, a third scan line SL3, and an emission control line EML, and a data line DL. The voltage lines may include first and second initialization voltage lines VIL1 and VIL2 and first and second driving voltage lines VDDL and VSSL.

The first driving voltage line VDDL may be a driving voltage line configured to transmit a first power voltage VDD to the first transistor T1. The first initialization voltage line VIL1 may transmit a first initialization voltage Vint for initializing a gate of the first transistor T1 to the pixel circuit PC. The second initialization voltage line VIL2 may transmit a second initialization voltage Vaint for initializing a first electrode of the light-emitting element LED to the pixel circuit PC.

The first transistor T1 may be electrically connected to the first driving voltage line VDDL via the fifth transistor T5, and may be electrically connected to the light-emitting element LED via the sixth transistor T6. The first transistor T1 serves as a driving transistor, receives a data signal Dm according to a switching operation of the second transistor T2, and supplies a driving current to the light-emitting element LED.

The second transistor T2 is electrically connected to the data line DL and a first node N1. A gate of the second transistor T2 is electrically connected to the first scan line SL1. The second transistor T2 is turned on in response to a first scan signal GW received through the first scan line SL1, and performs a switching operation of transmitting the data signal Dm transmitted through the data line DL to the first node N1.

The third transistor T3 is electrically connected to the gate of the first transistor T1 and one terminal of the first transistor T1. A gate of the third transistor T3 is electrically connected to the first scan line SL1. The third transistor T3 may be turned on in response to the first scan signal GW received through the first scan line SL1, and may diode-connect the first transistor T1 to compensate for a threshold voltage of the first transistor T1.

The fourth transistor T4 is electrically connected to the gate of the first transistor T1 and the first initialization voltage line VIL1. A gate of the fourth transistor T4 is electrically connected to the second scan line SL2. The fourth transistor T4 is turned on in response to a second scan signal GI received through the second scan line SL2, and transmits the first initialization voltage Vint from the first initialization voltage line VIL1 to the gate of the first transistor T1 to initialize a voltage of the gate of the first transistor T1.

The fifth transistor T5 is electrically connected to the first driving voltage line VDDL and the first node N1. The sixth transistor T6 is electrically connected to one terminal of the first transistor T1 and the light-emitting element LED. A gate of the fifth transistor T5 and a gate of the sixth transistor T6 are electrically connected to the emission control line EML. The fifth transistor T5 and the sixth transistor T6 are simultaneously turned on in response to an emission control signal EM received through the emission control line EML, and form a current path so that a driving current flows from the first driving voltage line VDDL to the light-emitting element LED.

The seventh transistor T7 may be electrically connected to the first electrode of the light-emitting element LED and the second initialization voltage line VIL2. A gate of the seventh transistor T7 may be electrically connected to the third scan line SL3. The seventh transistor T7 may be turned on in response to a third scan signal GB received through the third scan line SL3, and may transmit the second initialization voltage Vaint from the second initialization voltage line VIL2 to the first electrode of the light-emitting element LED to initialize the first electrode of the light-emitting element LED.

The capacitor Cst includes a first electrode CE1 and a second electrode CE2. The first electrode CE1 is electrically connected to the gate of the first transistor T1, and the second electrode CE2 is electrically connected to the first driving voltage line VDDL. The capacitor Cst may store and maintain a voltage corresponding to a voltage difference between the first driving voltage line VDDL and the gate of the first transistor T1, thereby maintaining a voltage applied to the gate of the first transistor T1.

Referring to FIG. 6B, the pixel circuit PC may include a first transistor T1, a second transistor T2, a third transistor T3, a fourth transistor T4, a fifth transistor T5, a sixth transistor T6, a seventh transistor T7, an eighth transistor T8, a ninth transistor T9, a first capacitor Cst, and a second capacitor Ca.

The pixel circuit PC is electrically connected to signal lines and voltage lines. The signal lines may include gate lines, such as a first scan line SL1, a second scan line SL2, a third scan line SL3, and an emission control line EML, and a data line DL. The voltage lines may include first and second initialization voltage lines VIL1 and VIL2, a sustain voltage line VSL, and first and second driving voltage lines VDDL and VSSL.

The first driving voltage line VDDL may transmit a first power voltage VDD to the first transistor T1. The first initialization voltage line VIL1 may transmit a first initialization voltage Vint for initializing a gate of the first transistor T1 to the pixel circuit PC. The second initialization voltage line VIL2 may transmit a second initialization voltage Vaint for initializing a first electrode of the light-emitting element LED to the pixel circuit PC. The sustain voltage line VSL may provide a sustain voltage VSUS to a second node N2, e.g., a second electrode CE2 of the first capacitor Cst, during an initialization section and a data writing section.

The first transistor T1 may be electrically connected to the first driving voltage line VDDL via the fifth transistor T5 and the eighth transistor T8, and may be electrically connected to the light-emitting element LED via the sixth transistor T6. The first transistor T1 may serve as a driving transistor, may receive a data signal Dm according to a switching operation of the second transistor T2, and may supply a driving current to the light-emitting element LED.

The second transistor T2 is electrically connected to the data line DL and a first node N1. A gate of the second transistor T2 is electrically connected to the first scan line SL1. The second transistor T2 is turned on in response to a first scan signal GW received through the first scan line SL1, and performs a switching operation of transmitting the data signal Dm transmitted through the data line DL to the first node N1.

The third transistor T3 is electrically connected to the gate of the first transistor T1 and one terminal of the first transistor T1. A gate of the third transistor T3 is electrically connected to the first scan line SL1. The third transistor T3 may be turned on in response to the first scan signal GW received through the first scan line SL1, and may diode-connect the first transistor T1 to compensate for a threshold voltage of the first transistor T1.

The fourth transistor T4 is electrically connected to the gate of the first transistor T1 and the first initialization voltage line VIL1. A gate of the fourth transistor T4 is electrically connected to the second scan line SL2. The fourth transistor T4 is turned on in response to a second scan signal GI received through the second scan line SL2, and transmits the first initialization voltage Vint from the first initialization voltage line VIL1 to the gate of the first transistor T1 to initialize a voltage of the gate of the first transistor T1.

The fifth transistor T5 is electrically connected to the second node N2 and the first node N1. The sixth transistor T6 is electrically connected to one terminal of the first transistor T1 and the light-emitting element LED. The eighth transistor T8 is electrically connected to the first driving voltage line VDDL and the second node N2. A gate of the fifth transistor T5, a gate of the sixth transistor T6, and a gate of the eighth transistor T8 are electrically connected to the emission control line EML. The fifth transistor T5, the sixth transistor T6, and the eighth transistor T8 are simultaneously turned on in response to an emission control signal EM received through the emission control line EML, and form a current path so that a driving current flows from the first driving voltage line VDDL to the light-emitting element LED.

The seventh transistor T7 may be electrically connected to the first electrode of the light-emitting element LED and the second initialization voltage line VIL2. A gate of the seventh transistor T7 may be electrically connected to the second scan line SL2. The seventh transistor T7 may be turned on in response to a third scan signal GB received through the third scan line SL3, and may transmit the second initialization voltage Vaint from the second initialization voltage line VIL2 to the first electrode of the light-emitting element LED to initialize the first electrode of the light-emitting element LED.

The ninth transistor T9 is electrically connected to the second node N2 and the sustain voltage line VSL. A gate of the ninth transistor T9 is electrically connected to the third scan line SL3. The ninth transistor T9 may be turned on in response to the third scan signal GB received through the third scan line SL3, and may transmit the sustain voltage VSUS to the second node N2, e.g., the second electrode CE2 of the first capacitor Cst, during an initialization section and a data writing section.

In some embodiments, during an initialization section and a data writing section, the eighth transistor T8 may be turned off and the ninth transistor T9 may be turned on, and during an emission section, the eighth transistor T8 may be turned on and the ninth transistor T9 may be turned off. Because the sustain voltage VSUS is transmitted to the second node N2 during the initialization section and the data writing section, the uniformity (e.g., long range uniformity (“LRU”)) in luminance of the display panel according to a voltage drop of the first driving voltage line VDDL may be improved.

The first capacitor Cst includes a first electrode CE1 and a second electrode CE2. The first electrode CE1 is electrically connected to the gate of the first transistor T1, and the second electrode CE2 is electrically connected to the eighth transistor T8 and the ninth transistor T9.

The second capacitor Ca is electrically connected to the first electrode of the light-emitting element LED and the sustain voltage line VSL. The second capacitor Ca may store and maintain a voltage corresponding to a voltage difference between the first electrode of the light-emitting element LED and the sustain voltage line VSL while the seventh transistor T7 and the ninth transistor T9 are turned on, thereby preventing an increase in black luminance when the sixth transistor T6 is turned off.

In FIGS. 6A and 6B, the light-emitting element LED may be connected to the first transistor T1 through the sixth transistor T6. The light-emitting element LED may include a first electrode (pixel electrode, anode) and a second electrode (cathode). In FIG. 6A, the first electrode of the light-emitting element LED may be connected to a second terminal of the sixth transistor T6 and a first terminal of the seventh transistor T7. In FIG. 6B, the first electrode of the light-emitting element LED may be connected to a second terminal of the sixth transistor T6, a first terminal of the seventh transistor T7, and the second capacitor Ca. The second electrode of the light-emitting element LED may be connected to the second driving voltage line VSSL configured to provide a second power supply voltage VSS.

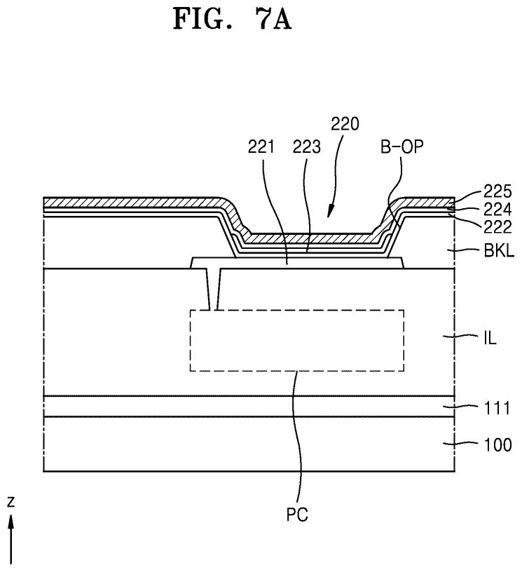

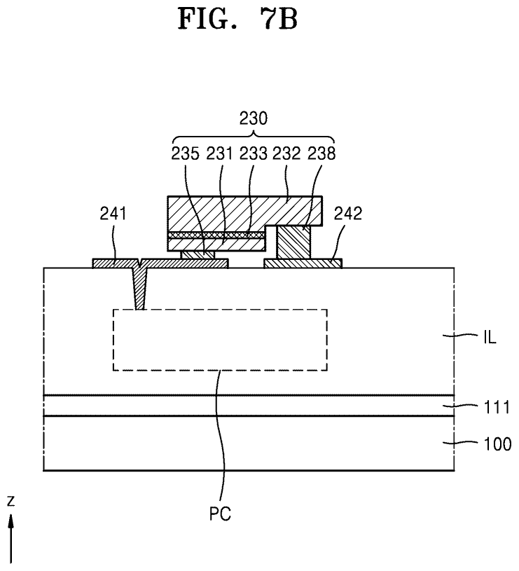

FIG. 7A is a schematic cross-sectional view of an embodiment of a light-emitting element of a display panel.

Referring to FIG. 7A, the light-emitting element in an embodiment may include an organic light-emitting diode 220 including an organic material. The organic light-emitting diode 220 may include a first electrode 221 disposed on the insulating layer IL, a second electrode 225 facing the first electrode 221, and an emission layer 223 disposed between the first electrode 221 and the second electrode 225. A first functional layer 222 may be disposed between the first electrode 221 and the emission layer 223, and a second functional layer 224 may be disposed between the emission layer 223 and the second electrode 225. The first electrode 221 may be connected to the pixel circuit PC.

An edge of the first electrode 221 may be covered by a bank layer BKL including an insulating material. The bank layer BKL may define an opening B-OP overlapping a portion of the first electrode 221.

The first electrode 221 may include a conductive oxide such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In another embodiment, the first electrode 221 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or any combinations thereof. In another embodiment, the first electrode 221 may further include a layer including ITO, IZO, ZnO, AZO, or In₂O₃ above/below the above-described reflective layer.

The emission layer 223 may include a polymer or low-molecular weight organic material for emitting light of a predetermined color. The first functional layer 222 may include a hole transport layer (“HTL”) and/or a hole injection layer (“HIL”). The second functional layer 224 may include an electron transport layer (“ETL”) and/or an electron injection layer (“EIL”).

The second electrode 225 may include a conductive material having a relatively low work function. In an embodiment, the second electrode 225 may include a (semi-)transparent layer including Ag, Mg, Al, Pt, Pd, Au, Ni, Nd, Ir, Cr, lithium (Li), calcium (Ca), or any alloys thereof. In an alternative embodiment, the second electrode 225 may further include a layer including ITO, IZO, ZnO, AZO, or In₂O₃ on the (semi-)transparent layer including the above-described material.

FIG. 7B is a schematic cross-sectional view of an embodiment of a light-emitting element of a display panel.

Referring to FIG. 7B, the light-emitting element in an embodiment may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be respectively electrically connected to a first electrode pad 241 and a second electrode pad 242, which are disposed in the same layer. The first electrode pad 241 may be connected to the pixel circuit PC.

In some embodiments, the first semiconductor layer 231 may include a p-type semiconductor layer. The p-type semiconductor layer may include or consist of semiconductor materials having a composition formula of InₓAl_{y}Ga_{1-x-y}N (where 0≤x≤1, 0≤y≤1, and 0≤x+y≤1), such as GaN, AlN, AlGaN, InGaN, InN, InAlGaN, and AlInN, and may be doped with a p-type dopant such as Mg, Zn, Ca, Sr, or Ba.

The second semiconductor layer 232 may include, e.g., an n-type semiconductor layer. The n-type semiconductor layer may include or consist of semiconductor materials having a composition formula of InₓAl_{y}Ga_{1-x-y}N (where 0≤x≤1, 0≤y≤1, and 0≤x+y≤1), such as GaN, AlN, AlGaN, InGaN, InN, InAlGaN, and AlInN, and may be doped with an n-type dopant such as Si, Ge, or Sn.

The intermediate layer 233 may be an area in which electrons and holes recombine, may transition to a relatively low energy level as the electrons and holes recombine, and may generate light having a corresponding wavelength. In an embodiment, the intermediate layer 233 may be formed to include a semiconductor material having a composition formula of InₓAl_{y}Ga_{1-x-y}N (where 0≤x≤1, 0≤y≤1, and 0≤x+y≤1), and may be formed in a single quantum well structure or a multi quantum well (“MQW”) structure. Also, the intermediate layer 233 may include a quantum wire structure or a quantum dot structure.

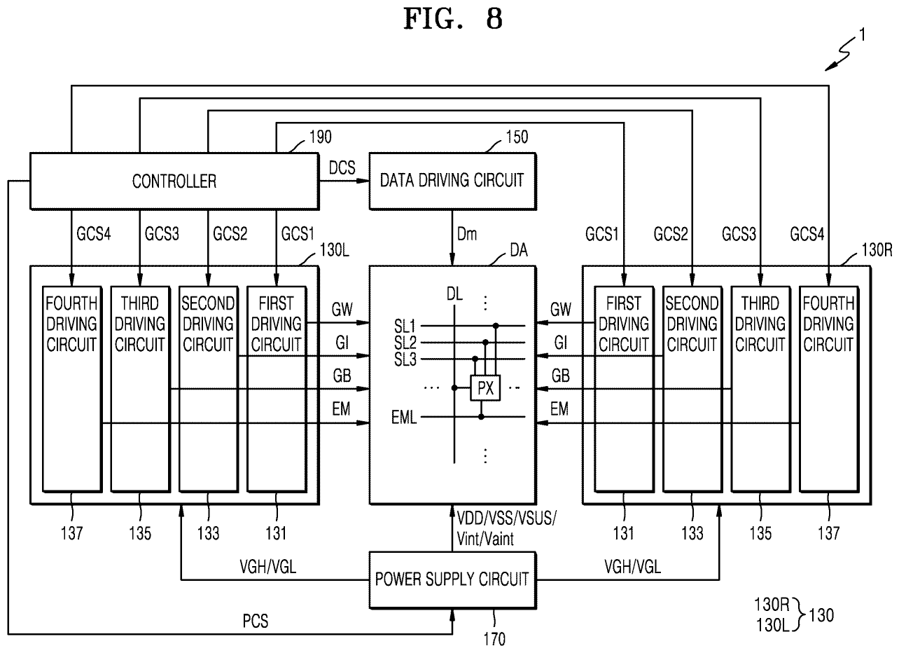

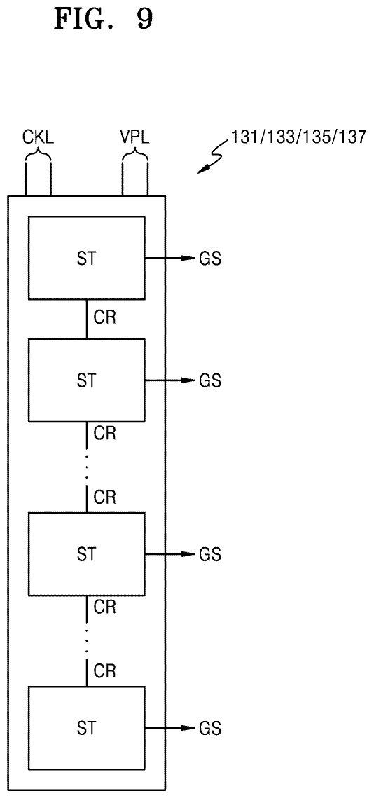

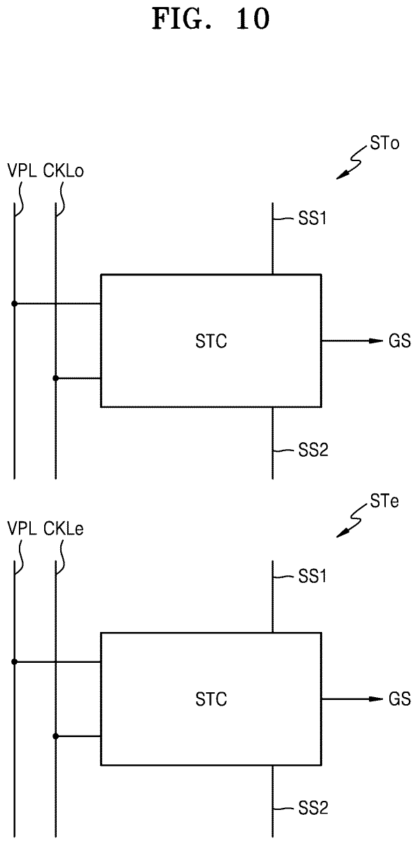

FIG. 8 is a schematic view of an embodiment of a display panel. FIG. 9 is a schematic view of an embodiment of a gate driving circuit. FIG. 10 is a schematic view of an embodiment of arbitrary stages constituting a gate driving circuit.

In an embodiment, a gate driving circuit 130 and a data driving circuit 150 shown in FIG. 8 may respectively correspond to the gate driving circuit GDC and the data driving circuit DDC of FIG. 3. Hereinafter, detailed descriptions of components overlapping those of the display panel shown in FIGS. 1 and 3 are omitted.

Referring to FIG. 8, the gate driving circuit 130 may include a first gate driving circuit 130L disposed on the left side of the display area DA and a second gate driving circuit 130R disposed on the right side of the display area DA. The first gate driving circuit 130L and the second gate driving circuit 130R may each include a first driving circuit 131, a second driving circuit 133, a third driving circuit 135, and a fourth driving circuit 137.

The first driving circuit 131 may be connected to a plurality of first scan lines SL1, and may sequentially supply a first scan signal GW to the first scan lines SL1 in response to a first driving control signal GCS1. The second driving circuit 133 may be connected to a plurality of second scan lines SL2, and may sequentially supply a second scan signal GI to the second scan lines SL2 in response to a second driving control signal GCS2. The third driving circuit 135 may be connected to a plurality of third scan lines SL3, and may sequentially supply a third scan signal GB to the third scan lines SL3 in response to a third driving control signal GCS3. The fourth driving circuit 137 may be connected to a plurality of emission control lines EML, and may sequentially supply an emission control signal EM to the emission control lines EML in response to a fourth driving control signal GCS4.

The data driving circuit 150 may be connected to a plurality of data lines DL, and may apply a data signal Dm representing grayscale to the data lines DL, in response to a fifth driving control signal DCS. The data driving circuit 150 may convert input image data having grayscale input from a controller 190 into a data signal Dm in the form of voltage or current.

A power supply circuit 170 may generate voltages desired for driving the pixel PX, in response to a sixth control signal PCS. In an embodiment, the power supply circuit 170 may transmit each of a first power voltage VDD, a second power voltage VSS, a first initialization voltage Vint, a second initialization voltage Vaint, and a sustain voltage VSUS to the display area DA through a global voltage line of the non-display area.

The power supply circuit 170 may generate a first voltage VGH and a second voltage VGL, which are desired for driving the gate driving circuit 130, and transmit the same to the gate driving circuit 130. The first voltage VGH may be higher than the second voltage VGL.

Referring to FIG. 9, the first driving circuit 131, the second driving circuit 133, the third driving circuit 135, and the fourth driving circuit 137 may each include a plurality of stages ST, and each stage ST may be connected to at least one clock line CKL configured to transmit at least one clock signal and at least one voltage line VPL configured to transmit at least one voltage signal (e.g., the first voltage VGH and the second voltage VGL). Each stage ST may receive a start signal, and may output a gate signal GS. The start signal may include an external start signal and a carry signal CR output by a previous or subsequent stage. The gate signal GS may include the first to third scan signals GW, GI, and GB and the emission control signal EM.

As shown in FIG. 10, the plurality of stages ST may include odd-numbered stages STo and even-numbered stages STe. The odd-numbered stages STo and the even-numbered stages STe may each include a stage circuit STC, and the stage circuit STC may be connected to at least one voltage line VPL and at least one clock line CKLo or CKLe. The stage circuit STC may be connected to a first signal line SS1 configured to transmit a first signal and a second signal line SS2 configured to transmit a second signal. In an embodiment, the first signal and the second signal may be constant voltage signals of a first voltage level or a second voltage level, or clock signals that swing alternately between the first voltage level and the second voltage level. In an embodiment, the first voltage level may be a relatively high voltage level, and the second voltage level may be a relatively low voltage level.

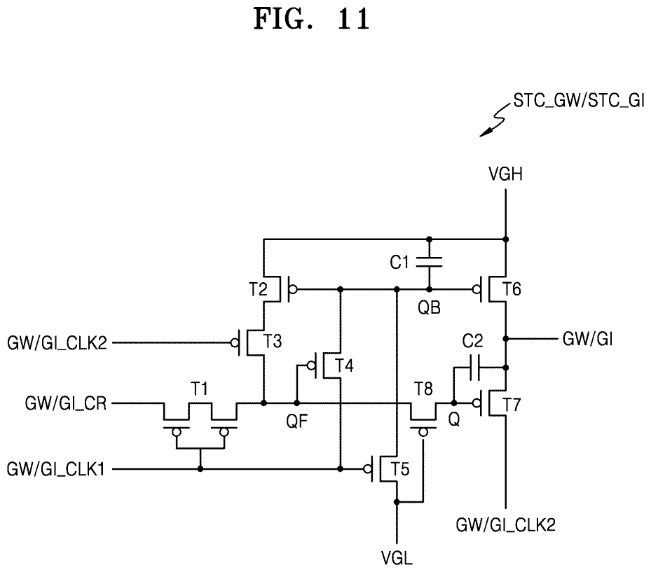

FIG. 11 is a schematic view of an embodiment of an arbitrary stage of the first driving circuit 131 or the second driving circuit 133. FIG. 11 may represent a stage of the first driving circuit 131 (hereinafter, a first stage) or a stage of the second driving circuit 133 (hereinafter, a second stage). A stage circuit STC_GW of the first stage is identical to a stage circuit STC_GI of the second stage.

Referring to FIG. 11, a stage circuit STC_GW/STC_GI may include first to eighth transistors T1 to T8 and first and second capacitors C1 and C2. In an embodiment, in an odd-numbered stage circuit STC_GW/STC_GI, a first clock signal GW/GI_CLK1 may be input to the first transistor T1, and a second clock signal GW/GI_CLK2 may be input to the third transistor T3 and the seventh transistor T7. In an even-numbered stage circuit STC_GW/STC_GI, a second clock signal GW/GI_CLK2 may be input to the first transistor T1, and a first clock signal GW/GI_CLK1 may be input to the third transistor T3 and the seventh transistor T7. FIG. 11 shows an embodiment of the odd-numbered stage circuit STC_GW/STC_GI.

The first transistor T1 may include two sub-transistors connected in series. The first transistor T1, when turned on by the first clock signal GW/GI_CLK1 input to a gate thereof, may transmit a start signal (e.g., a carry signal) GW/GI_CR to a node QF.

The second transistor T2 may be turned on when a voltage of a node QB to which a gate thereof is connected is at a relatively low level, and the third transistor T3 may be turned on when the second clock signal GW/GI_CLK2 input to a gate thereof is at a relatively low level. When the second transistor T2 and the third transistor T3 are turned on, a first voltage VGH may be transmitted to the node QF. Accordingly, when the voltage of the node QB is at a relatively low level, a voltage of the node QF may be at a relatively high level.

The fourth transistor T4 may be turned on when the voltage of the node QF to which a gate thereof is connected is at a relatively low level, and may transmit a high-level voltage of the first clock signal GW/GI_CLK1 to the node QB. Accordingly, when the voltage of the node QF is at a relatively low level, the voltage of the node QB may be at a relatively high level.

The fifth transistor T5 may be turned on when the first clock signal GW/GI_CLK1 input to a gate thereof is at a relatively low level, and may transmit a second voltage VGL to the node QB. Accordingly, when the voltage of the node QF is at a relatively high level, the voltage of the node QB may be at a relatively low level.

The sixth transistor T6 may be turned on when the voltage of the node QB is at a relatively low level, and the sixth transistor T6 that has been turned on may output the first voltage VGH as an output signal (first scan signal GW or second scan signal GI) to an output line.

The seventh transistor T7 may be turned on when a voltage of a node Q is at a relatively low level, and the seventh transistor T7 that has been turned on may output a low-level voltage of the second clock signal GW/GI_CLK2 as an output signal (first scan signal GW or second scan signal GI) to the output line.

The eighth transistor T8 may be turned on by receiving the second voltage VGL through a gate thereof, and may electrically connect the nodes QF and Q to each other.

The first capacitor C1 may store a voltage difference between a terminal thereof to which the first voltage VGH is input and a terminal thereof connected to the node QB. The second capacitor C2 may store a voltage difference between a terminal thereof connected to the output line and a terminal thereof connected to the node Q. Due to the coupling effect of the second capacitor C2, depending on a voltage fluctuation of the terminal thereof connected to the output line, the voltage of the node Q and/or the node QF may fluctuate.

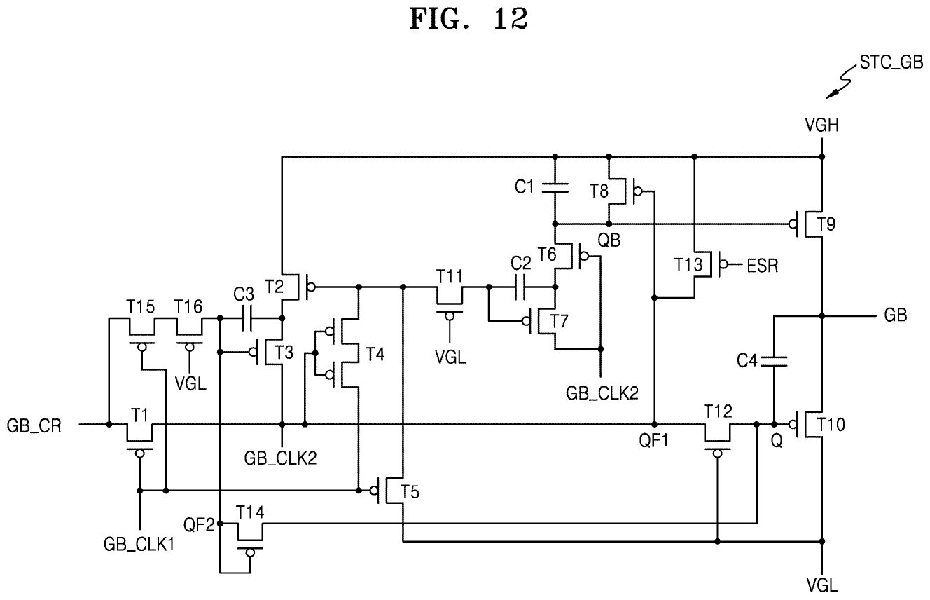

FIG. 12 is a schematic view of an embodiment of an arbitrary stage of the third driving circuit 135.

Referring to FIG. 12, a stage circuit STC_GB may include first to sixteenth transistors T1 to T16 and first to fourth capacitors C1 to C4. The fourth capacitor C4 may be omitted.

In an embodiment, in an odd-numbered stage circuit STC_GB, a first clock signal GB_CLK1 may be input to the first transistor T1, and a second clock signal GB_CLK2 may be input to the third transistor T3 and the seventh transistor T7. In an even-numbered stage circuit STC_GB, a second clock signal GB_CLK2 may be input to the first transistor T1, and a first clock signal GB_CLK1 may be input to the third transistor T3 and the seventh transistor T7. FIG. 12 shows an embodiment of the odd-numbered stage circuit STC_GB.

The first transistor T1 may be turned on when the first clock signal GB_CLK1 input to a gate thereof is at a relatively low level, and may transmit a start signal (e.g., a carry signal) GB_CR to a node QF1.

The second transistor T2 may be turned on when a voltage of a node to which a gate thereof is connected is at a relatively low level. The third transistor T3 may be turned on when a voltage of a node QF2 to which a gate thereof is connected is at a relatively low level. The fourth transistor T4 may include two sub-transistors connected in series. The fourth transistor T4 may be turned on when a voltage of the node QF1 to which a gate thereof is connected is at a relatively low level, and may transmit the first clock signal GB_CLK1 to the gate of the second transistor T2.

The fifth transistor T5 may be turned on when the first clock signal GB_CLK1 input to a gate thereof is at a relatively low level, and may transmit a second voltage VGL to the gate of the second transistor T2.

The sixth transistor T6 may be turned on when the second clock signal GB_CLK2 input to a gate thereof is at a relatively low level. The seventh transistor T7 may be turned on when a node to which a gate thereof is connected is at a relatively low level, and may transmit the second clock signal GB_CLK2 to one terminal of the second capacitor C2. The gate of the seventh transistor T7 may be connected to a remaining (the other) terminal of the second capacitor C2.

The eighth transistor T8 may be turned on when the voltage of the node QF1 to which a gate thereof is connected is at a relatively low level, and may transmit a first voltage VGH to a node QB.

The ninth transistor T9 may be turned on when a voltage of the node QB to which a gate thereof is connected is at a relatively low level, and may output the first voltage VGH as an output signal (third scan signal GB) to an output line.

The tenth transistor T10 may be turned on when a voltage of a node Q to which a gate thereof is connected is at a relatively low level, and may output the second voltage VGL as an output signal (third scan signal GB) to the output line.

The second voltage VGL may be input to a gate of the eleventh transistor T11, and the eleventh transistor T11 that has been turned on may electrically connect the node to which the gate of the second transistor T2 is connected and the node to which the gate of the seventh transistor T7 is connected to each other.

The second voltage VGL may be input to a gate of the twelfth transistor T12, and the twelfth transistor T12 that has been turned on may electrically connect the node QF1 and the node Q to each other.

The thirteenth transistor T13 may be turned on when a reset signal ESR of a relatively low level is applied thereto, and the node QF1 may be brought to a relatively high level due to the first voltage VGH, so that the tenth transistor T10 may remain turned off.

The fourteenth transistor T14 may be turned on when the voltage of the node QF2 to which a gate thereof is connected is at a relatively low level, and may electrically connect the node QF2 and the node Q to each other.

The fifteenth transistor T15 may be turned on when the first clock signal GB_CLK1 input to a gate thereof is at a relatively low level, and may transmit the start signal GB_CR. The second voltage VGL may be input to a gate of the sixteenth transistor T16, and the sixteenth transistor T16 that has been turned on may transmit the start signal GB_CR transmitted through the fifteenth transistor T15 to the node QF2.

The fourteenth transistor T14, the fifteenth transistor T15, the sixteenth transistor T16, and the third capacitor C3 may boost the start signal GB_CR at the node QF2 and transmit the boosted voltage to the node Q.

The first capacitor C1 may store a voltage difference between a terminal thereof to which the first voltage VGH is input and a terminal thereof connected to the node QB. The second capacitor C2 may store a voltage difference between the gate and one terminal of the seventh transistor T7. The third capacitor C3 may store a voltage difference between the gate and one terminal of the third transistor T3. The fourth capacitor C4 may store a voltage difference between a terminal thereof connected to the output line and a terminal thereof connected to the node Q.

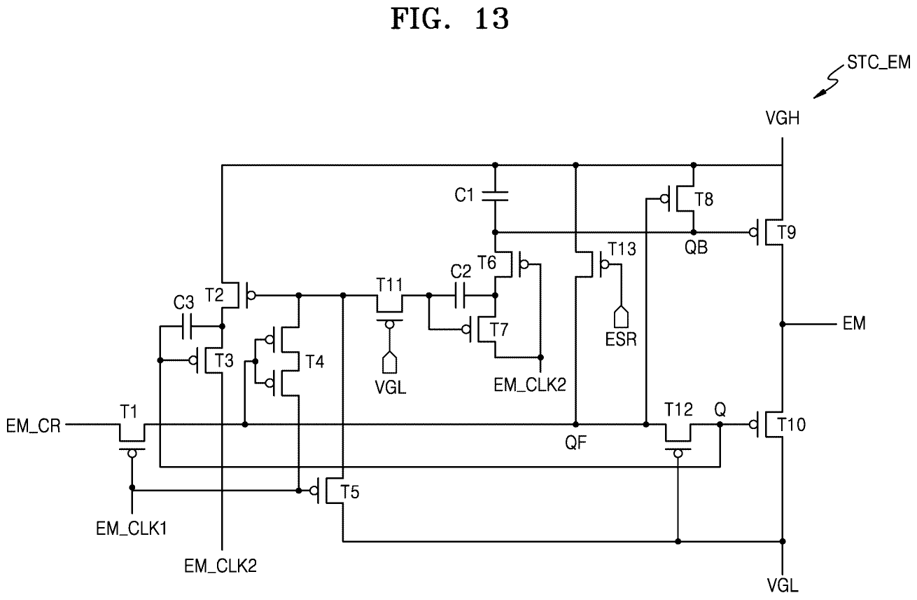

FIG. 13 is a schematic view of an embodiment of an arbitrary stage of the fourth driving circuit 137.

Referring to FIG. 13, a stage circuit STC_EM may include first to thirteenth transistors T1 to T13 and first to third capacitors C1 to C3.

In an embodiment, in an odd-numbered stage circuit STC_EM, a first clock signal EM_CLK1 may be input to the first transistor T1, and a second clock signal EM_CLK2 may be input to the third transistor T3, the sixth transistor T6, and the seventh transistor T7. In an even-numbered stage circuit STC_EM, a second clock signal EM_CLK2 may be input to the first transistor T1, and a first clock signal EM_CLK1 may be input to the third transistor T3, the sixth transistor T6, and the seventh transistor T7. FIG. 13 shows an embodiment of the odd-numbered stage circuit STC_EM.

In the stage circuit STC_EM of FIG. 13, the fourteenth to sixteenth transistors T14 to T16 and the fourth capacitor C4 are omitted from the stage circuit STC_GB of FIG. 12, and connection of some elements is different from that of the stage circuit STC_GB of FIG. 12.

The first transistor T1 may be turned on when the first clock signal EM_CLK1 input to a gate thereof is at a relatively low level, and may transmit a start signal (e.g., a carry signal) EM_CR to a node QF.

The second transistor T2 may be turned on when a voltage of a node to which a gate thereof is connected is at a relatively low level. The third transistor T3 may be turned on when a voltage of a node Q to which a gate thereof is connected is at a relatively low level. The fourth transistor T4 may include two sub-transistors connected in series. The fourth transistor T4 may be turned on when a voltage of the node QF to which a gate thereof is connected is at a relatively low level, and may transmit the first clock signal EM_CLK1 to the gate of the second transistor T2.

The fifth transistor T5 may be turned on when the first clock signal EM_CLK1 input to a gate thereof is at a relatively low level, and may transmit a second voltage VGL to the gate of the second transistor T2.

The sixth transistor T6 may be turned on when the second clock signal EM_CLK2 input to a gate thereof is at a relatively low level. The seventh transistor T7 may be turned on when a node to which a gate thereof is connected is at a relatively low level, and may transmit the second clock signal EM_CLK2 to one terminal of the second capacitor C2. The gate of the seventh transistor T7 may be connected to a remaining (the other) terminal of the second capacitor C2.

The eighth transistor T8 may be turned on when the voltage of the node QF to which a gate thereof is connected is at a relatively low level, and may transmit a first voltage VGH to a node QB.

The ninth transistor T9 may be turned on when a voltage of the node QB to which a gate thereof is connected is at a relatively low level, and may output the first voltage VGH as an output signal (emission control signal EM) to an output line.

The tenth transistor T10 may be turned on when the voltage of the node Q to which a gate thereof is connected is at a relatively low level, and may output the second voltage VGL as an output signal (emission control signal EM) to the output line.

The second voltage VGL may be input to a gate of the eleventh transistor T11, and the eleventh transistor T11 that has been turned on may electrically connect the node to which the gate of the second transistor T2 is connected and the node to which the gate of the seventh transistor T7 is connected to each other.

The second voltage VGL may be input to a gate of the twelfth transistor T12, and the twelfth transistor T12 that has been turned on may electrically connect the node QF and the node Q to each other.

The thirteenth transistor T13 may be turned on when a reset signal ESR of a relatively low level is applied thereto, and the node QF may be brought to a relatively high level due to the first voltage VGH, so that the tenth transistor T10 may remain turned off.

The first capacitor C1 may store a voltage difference between a terminal thereof to which the first voltage VGH is input and a terminal thereof connected to the node QB. The second capacitor C2 may store a voltage difference between the gate and one terminal of the seventh transistor T7. The third capacitor C3 may store a voltage difference between the gate and one terminal of the third transistor T3.

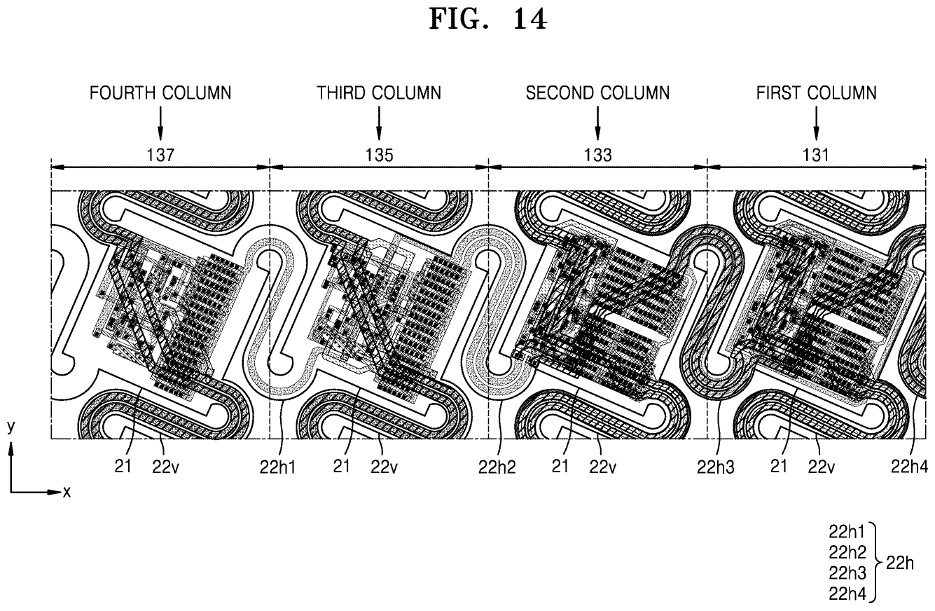

FIG. 14 is a schematic plan view of an embodiment of a portion of the gate driving circuit 130.

The gate driving circuit 130 may be disposed in the first non-display area NDA1 (FIG. 3) and/or the second non-display area NDA2 (FIG. 3). Referring to FIG. 14, the gate driving circuit 130 may include a first driving circuit 131, a second driving circuit 133, a third driving circuit 135, and a fourth driving circuit 137. The first driving circuit 131 may be disposed closest to the display area DA, and the fourth driving circuit 137 may be disposed farthest from the display area DA. The first driving circuit 131 may be disposed in a first column, the second driving circuit 133 may be disposed in a second column next (adjacent) to the first column, the third driving circuit 135 may be disposed in a third column next (adjacent) to the second column, and the fourth driving circuit 137 may be disposed in a fourth column next (adjacent) to the third column. FIG. 14 shows a stage of the first driving circuit 131 (hereinafter, a first stage), a stage of the second driving circuit 133 (hereinafter, a second stage), a stage of the third driving circuit 135 (hereinafter, a third stage), and a stage of the fourth driving circuit 137 (hereinafter, a fourth stage), which are arranged in arbitrary rows.

A plurality of second island portions 21 and a plurality of second bridge portions 22 connecting the second island portions 21 to each other may be arranged in each of the first to fourth columns. The second bridge portions 22 may include horizontal bridge portions 22h extending in the first direction and vertical bridge portions 22v extending in the second direction. At least one horizontal conductive line extending in the first direction may be disposed in the horizontal bridge portion 22h. At least one vertical conductive line extending in the second direction may be disposed in the vertical bridge portion 22v. In a plan view, the at least one horizontal conductive line and the at least one vertical conductive line may extend across the second island portion 21. The at least one horizontal conductive line and the at least one vertical conductive line may extend with curves along the shapes of the horizontal bridge portion 22h and the vertical bridge portion 22v. In an embodiment, two second bridge portions 22 in different columns may be also referred to as a first area bridge portion and a second area bridge portion, respectively.

Hereinafter, for convenience of description, the horizontal bridge portions 22h arranged in respective rows are also referred to as a first horizontal bridge portion 22h1, a second horizontal bridge portion 22h2, a third horizontal bridge portion 22h3, and a fourth horizontal bridge portion 22h4, in the direction toward the display area DA along the first direction.

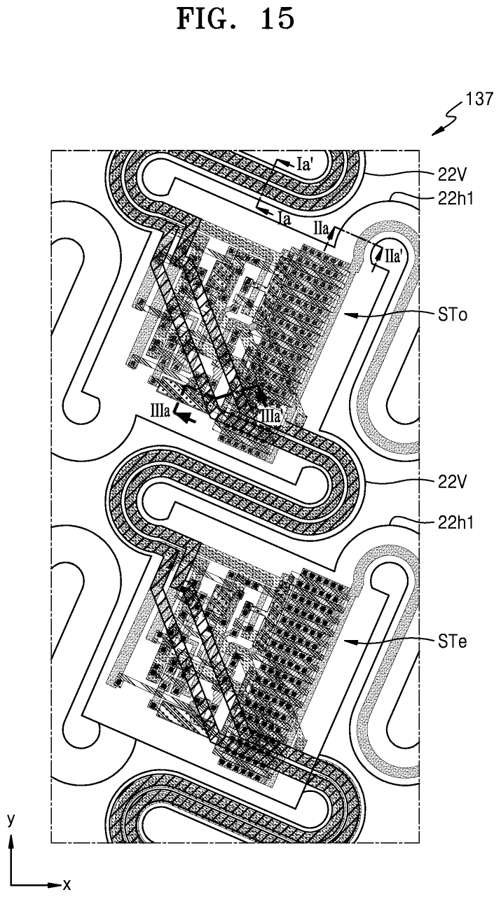

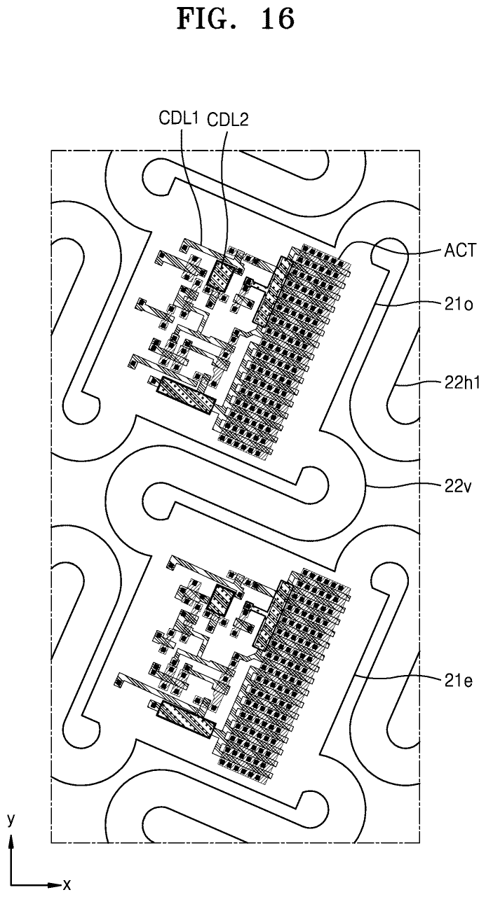

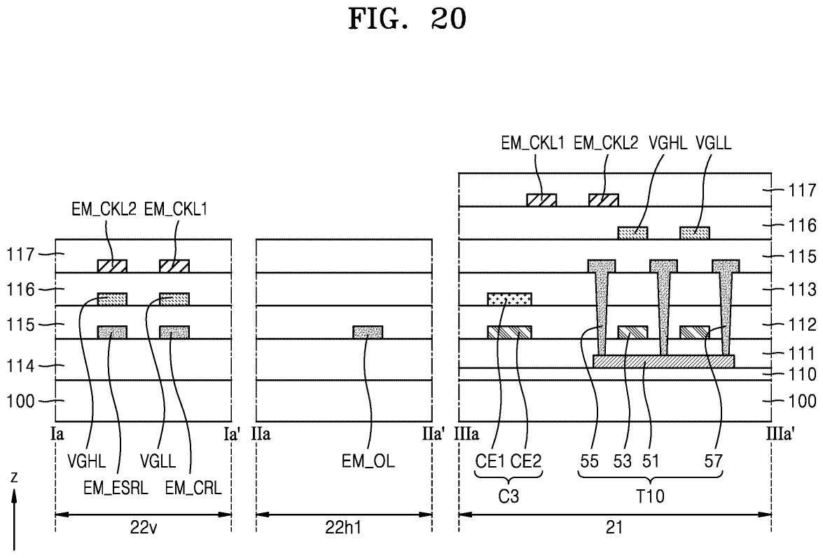

FIG. 15 is a schematic view of an embodiment of a portion of the fourth driving circuit 137. FIGS. 16 to 19 are schematic views of components of each layer of the fourth driving circuit 137 shown in FIG. 15. FIG. 20 is a cross-sectional view of the fourth driving circuit 137 shown in FIG. 15, taken along lines Ia-Ia′, IIa-IIa′, and IIIa-IIIa′.

The fourth stage of the fourth driving circuit 137 may be disposed in the second island portion 21 of the fourth column. FIG. 15 shows an odd-numbered stage STo and an even-numbered stage STe of the fourth driving circuit 137, which are next (adjacent) to each other in the second direction. Referring to FIG. 15, the odd-numbered stage STo may be disposed in a second island portion 21o of an odd-numbered row (hereinafter, an odd-numbered second island portion 21o), and the even-numbered stage STe may be disposed in a second island portion 21e of an even-numbered row (hereinafter, an even-numbered second island portion 21e).

Referring to FIG. 16, a semiconductor layer ACT, a first conductive layer CDL1, and a second conductive layer CDL2 may be sequentially arranged in the second island portion 21. A barrier layer 110 (FIG. 20) may be disposed between a substrate 100 (FIG. 20) and the semiconductor layer ACT. The semiconductor layer ACT may include a silicon semiconductor. The semiconductor layer ACT may include a channel region, and a source region and a drain region, which are on two sides of the channel region, of each of the first to thirteenth transistors T1 to T13 (FIG. 13). In some cases, the source region or the drain region may be interpreted as a source electrode or a drain electrode of a transistor.

A first insulating layer 111 (FIG. 20) may be disposed on the barrier layer 110 to cover the semiconductor layer ACT, and the first conductive layer CDL1 may be disposed on the first insulating layer 111. The first conductive layer CDL1 may include a gate electrode of each of the first to thirteenth transistors T1 to T13 and a lower electrode of each of the first to third capacitors C1 to C3 (FIG. 13). The gate electrodes may overlap the channel regions of the semiconductor layer ACT.

A second insulating layer 112 (FIG. 20) may be disposed on the first insulating layer 111 to cover the first conductive layer CDL1, and the second conductive layer CDL2 may be disposed on the second insulating layer 112. The second conductive layer CDL2 may include an upper electrode of each of the first to third capacitors C1 to C3. The upper electrode of each of the first to third capacitors C1 to C3 may overlap the lower electrode of each of the first to third capacitors C1 to C3.

A third insulating layer 113 (FIG. 20) may be disposed on the second insulating layer 112 to cover the second conductive layer CDL2, and contact holes may be defined in the first insulating layer 111, the second insulating layer 112, and the third insulating layer 113.

Thereafter, areas other than the area corresponding to the second island portion 21 may be removed from the barrier layer 110, the first insulating layer 111, the second insulating layer 112, and the third insulating layer 113, so that openings corresponding to the areas other than the area corresponding to the second island portion 21 may be defined in the barrier layer 110, the first insulating layer 111, the second insulating layer 112, and the third insulating layer 113. That is, the barrier layer 110, the first insulating layer 111, the second insulating layer 112, and the third insulating layer 113 may not be arranged in the second bridge portions 22, but may be arranged in the second island portion 21. The barrier layer 110, the first insulating layer 111, the second insulating layer 112, and the third insulating layer 113 may have an island shape corresponding to the second island portion 21.

A fourth insulating layer 114 may be disposed in an area other than the area corresponding to the second island portion 21 of the substrate 100. That is, the fourth insulating layer 114 may not be disposed in the second island portion 21, but may be disposed in the second bridge portion 22.

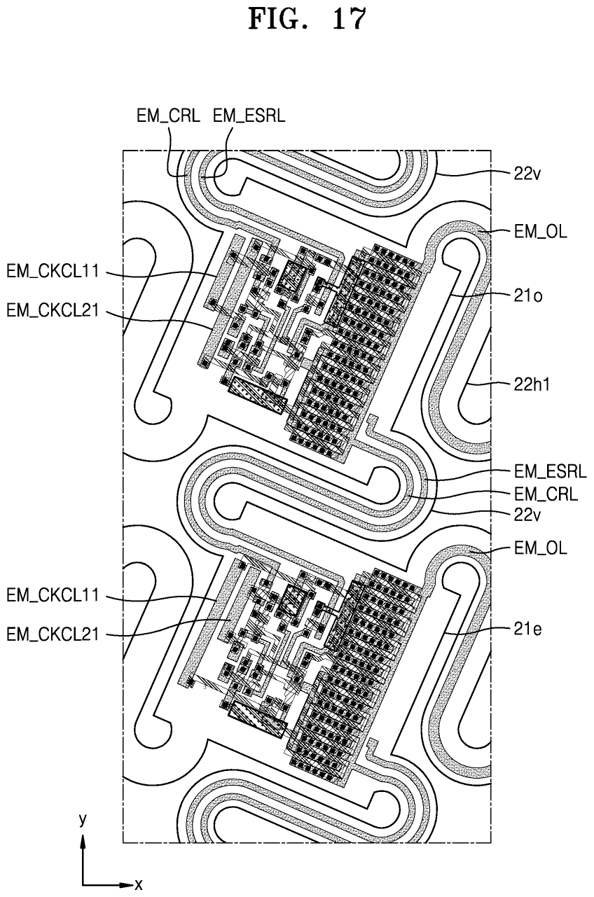

Referring to FIG. 17, a third conductive layer may be disposed on the third insulating layer 113 of the second island portion 21 and the fourth insulating layer 114 of the second bridge portion 22. The third conductive layer may include a first clock connection line EM_CKCL11, a second clock connection line EM_CKCL21, source electrodes and drain electrodes, a carry line EM_CRL configured to transmit a start signal or a previous carry signal, a reset line EM_ESRL configured to transmit a reset signal, and an output line (hereinafter, a fourth output line) EM_OL configured to output an emission control signal EM. In the disclosure, the output line (e.g., the fourth output line EM_OL) may be also referred to as a first conductive line.

The first clock connection line EM_CKCL11 and the second clock connection line EM_CKCL21 may be arranged in the second island portion 21. In the odd-numbered second island portion 21o, the first clock connection line EM_CKCL11 may be connected to the gate electrode of the first transistor T1, and the second clock connection line EM_CKCL21 may be connected to one of the source electrode and drain electrode of the third transistor T3, the gate electrode of the sixth transistor T6, and one of the source electrode and drain electrode of the seventh transistor T7. In the even-numbered second island portion 21e, the first clock connection line EM_CKCL11 may be connected to one of the source electrode and drain electrode of the third transistor T3, the gate electrode of the sixth transistor T6, and one of the source electrode and drain electrode of the seventh transistor T7, and the second clock connection line EM_CKCL21 may be connected to the gate electrode of the first transistor T1.

The source electrodes and drain electrodes may be arranged in the second island portion 21. Each of the source electrodes may be connected to a corresponding source region of the semiconductor layer ACT, and each of the drain electrodes may be connected to a corresponding drain region of the semiconductor layer ACT.

The fourth output line EM_OL may be disposed in the first horizontal bridge portion 22h1, and the carry line EM_CRL and the reset line EM_ESRL may be disposed apart from each other in the vertical bridge portion 22v. In the disclosure, a horizontal bridge (e.g., first horizontal bridge portion 22h1) may be also referred to as a first directional bridge portion, and the vertical bridge portion 22v may be also referred to as a second directional bridge portion. The fourth output line EM_OL may extend from one of the source electrode and drain electrode of the ninth transistor T9 and one of the source electrode and drain electrode of the tenth transistor T10. The carry line EM_CRL may be connected to one of the source electrode and drain electrode of the first transistor T1. The reset line EM_ESRL may be connected to the gate electrode of the thirteenth transistor T13.

A fifth insulating layer 115 (FIG. 20) may be disposed on the third insulating layer 113 of the second island portion 21 and the fourth insulating layer 114 of the second bridge portion 22 to cover the third conductive layer. Contact holes may be defined in the fifth insulating layer 115.

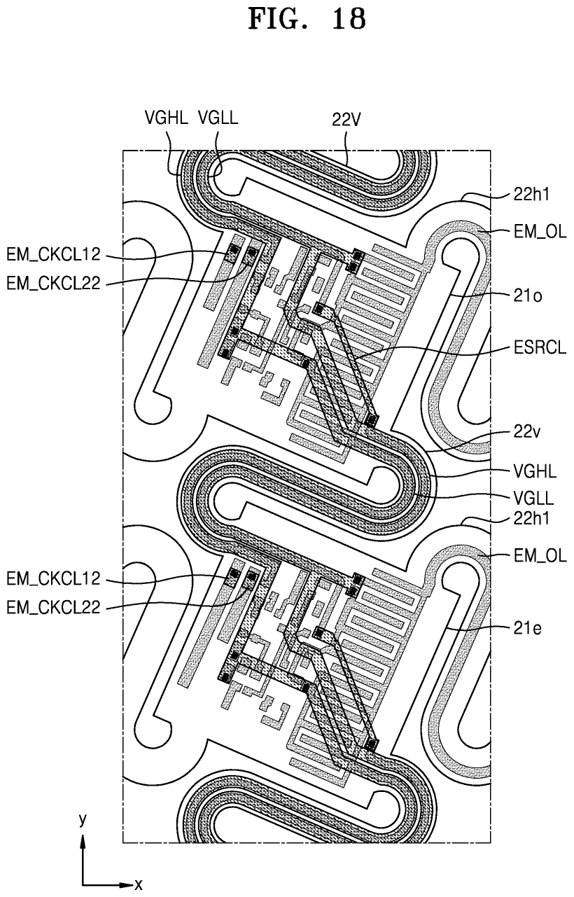

Referring to FIG. 18, a fourth conductive layer may be disposed on the fifth insulating layer 115. The fourth conductive layer may include a first clock connection electrode EM_CKCL12, a second clock connection electrode EM_CKCL22, a reset connection line ESRCL, a first voltage line VGHL configured to transmit a first voltage VGH, and a second voltage line VGLL configured to transmit a second voltage VGL.

The first clock connection electrode EM_CKCL12, the second clock connection electrode EM_CKCL22, and the reset connection line ESRCL may be arranged in the second island portion 21. The first clock connection electrode EM_CKCL12 may be connected to the first clock connection line EM_CKCL11, and the second clock connection electrode EM_CKCL22 may be connected to the second clock connection line EM_CKCL21. The reset connection line ESRCL may connect the reset lines EM_ESRL, which are arranged in the vertical bridge portions 22v arranged in the second direction with the second island portion 21 therebetween, to each other.

The first voltage line VGHL and the second voltage line VGLL may be arranged in the vertical bridge portion 22v, and the first voltage line VGHL and the second voltage line VGLL may extend across the second island portion 21. In the second island portion 21, the first voltage line VGHL may be connected to one of the source electrode and drain electrode of the second transistor T2, one of the source electrode and drain electrode of the eighth transistor T8, one of the source electrode and drain electrode of the ninth transistor T9, one of the source electrode and drain electrode of the thirteenth transistor T13, and one electrode of the first capacitor C1. The second voltage line VGLL may be connected to one of the source electrode and drain electrode of the fifth transistor T5, one of the source electrode and drain electrode of the tenth transistor T10, and the gate electrode of the twelfth transistor T12.

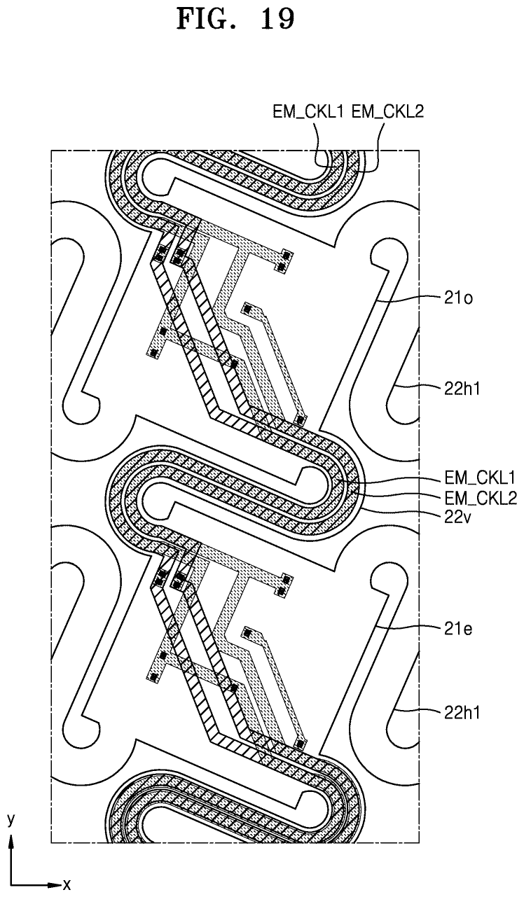

Referring to FIG. 19, a sixth insulating layer 116 (FIG. 20) may be disposed on the fifth insulating layer 115 to cover the fourth conductive layer. Contact holes may be defined in the sixth insulating layer 116. A fifth conductive layer may be disposed on the sixth insulating layer 116. The fifth conductive layer may include a first clock line EM_CKL1 and a second clock line EM_CKL2.

The first clock line EM_CKL1 and the second clock line EM_CKL2 may be arranged in the vertical bridge portion 22v. The first clock line EM_CKL1 and the second clock line EM_CKL2 may extend across the second island portion 21. In the second island portion 21, the first clock line EM_CKL1 may be connected to the first clock connection electrode EM_CKCL12, and the second clock line EM_CKL2 may be connected to the second clock connection electrode EM_CKCL22.

In the disclosure, the voltage line (e.g., the first voltage line VGHL and the second voltage line VGLL) and the clock line (e.g., first clock line EM_CKL1 and the second clock line EM_CKL2) may be also referred to as a second conductive line.

A seventh insulating layer 117 (FIG. 20) may be disposed on the sixth insulating layer 116 to cover the fifth conductive layer.

As shown in FIG. 20, in the vertical bridge portion 22v, the first voltage line VGHL may overlap the reset line EM_ESRL, and the second voltage line VGLL may overlap the carry line EM_CRL. The first clock line EM_CKL1 may overlap the second voltage line VGLL, and the second clock line EM_CKL2 may overlap the first voltage line VGHL.

FIG. 20 shows a semiconductor layer 51, a gate electrode 53, a source electrode 55, and a drain electrode 57 of the tenth transistor T10, and a lower electrode CE1 and an upper electrode CE2 of the third capacitor C3, which are arranged in the second island portion 21.

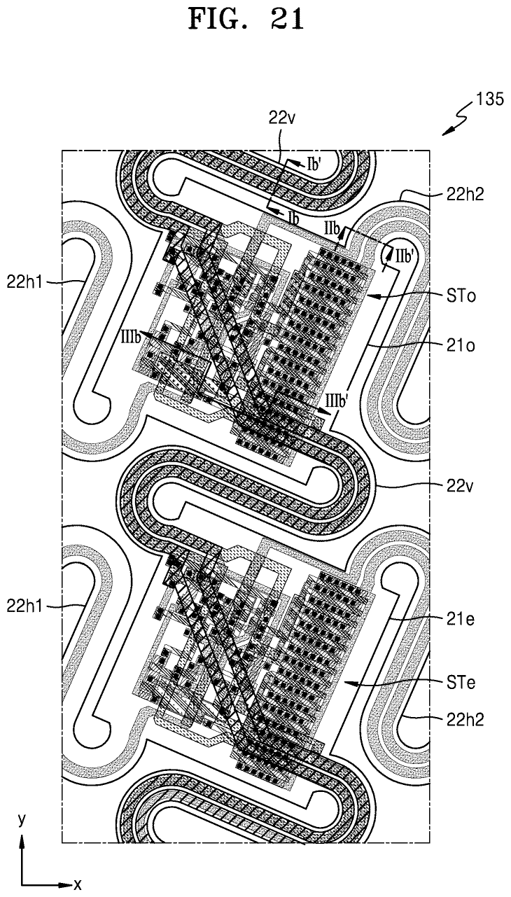

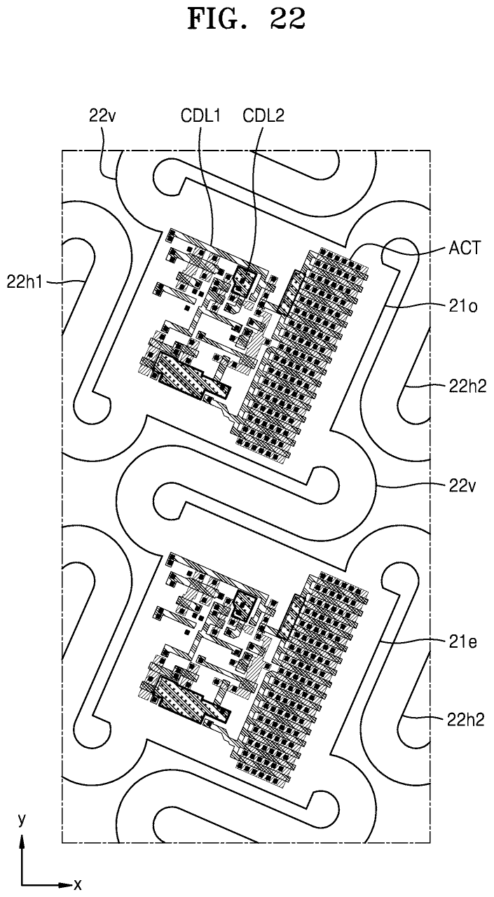

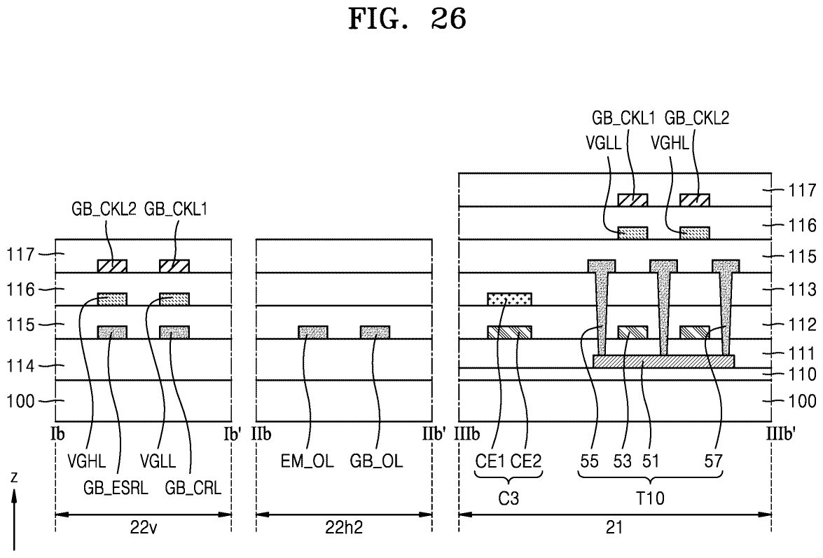

FIG. 21 is a schematic view of an embodiment of a portion of the third driving circuit 135. FIGS. 22 to 25 are schematic views of components of each layer of the third driving circuit 135 shown in FIG. 21. FIG. 26 is a cross-sectional view of the third driving circuit 135 shown in FIG. 21, taken along lines Ib-Ib′, IIb-IIb′, and IIIb-IIIb′.

The third stage of the third driving circuit 135 may be disposed in the second island portion 21 of the third column. FIG. 21 shows an odd-numbered stage STo and an even-numbered stage STe of the third driving circuit 135, which are next (adjacent) to each other in the second direction. Referring to FIG. 21, the odd-numbered stage STo may be disposed in an odd-numbered second island portion 21o, and the even-numbered stage STe may be disposed in an even-numbered second island portion 21e.

Referring to FIG. 22, a semiconductor layer ACT, a first conductive layer CDL1, and a second conductive layer CDL2 may be sequentially arranged in the second island portion 21. A barrier layer 110 (FIG. 26) may be disposed between a substrate 100 (FIG. 26) and the semiconductor layer ACT. The semiconductor layer ACT may include a silicon semiconductor. The semiconductor layer ACT may include a channel region, and a source region and a drain region, which are on two sides of the channel region, of each of the first to sixteenth transistors T1 to T16 (FIG. 12). In some cases, the source region or the drain region may be interpreted as a source electrode or a drain electrode of a transistor.

A first insulating layer 111 (FIG. 26) may be disposed on the barrier layer 110 to cover the semiconductor layer ACT, and the first conductive layer CDL1 may be disposed on the first insulating layer 111. The first conductive layer CDL1 may include a gate electrode of each of the first to sixteenth transistors T1 to T16 and a lower electrode of each of the first to third capacitors C1 to C3 (FIG. 12). The gate electrodes may overlap the channel regions of the semiconductor layer ACT.

A second insulating layer 112 (FIG. 26) may be disposed on the first insulating layer 111 to cover the first conductive layer CDL1, and the second conductive layer CDL2 may be disposed on the second insulating layer 112. The second conductive layer CDL2 may include an upper electrode of each of the first to third capacitors C1 to C3. The upper electrode of each of the first to third capacitors C1 to C3 may overlap the lower electrode of each of the first to third capacitors C1 to C3.

A third insulating layer 113 (FIG. 26) may be disposed on the second insulating layer 112 to cover the second conductive layer CDL2, and contact holes may be defined in the first insulating layer 111, the second insulating layer 112, and the third insulating layer 113.

Thereafter, as described with reference to FIG. 17, areas other than the area corresponding to the second island portion 21 may be removed from the barrier layer 110, the first insulating layer 111, the second insulating layer 112, and the third insulating layer 113. A fourth insulating layer 114 may be disposed in an area other than the area corresponding to the second island portion 21 of the substrate 100.

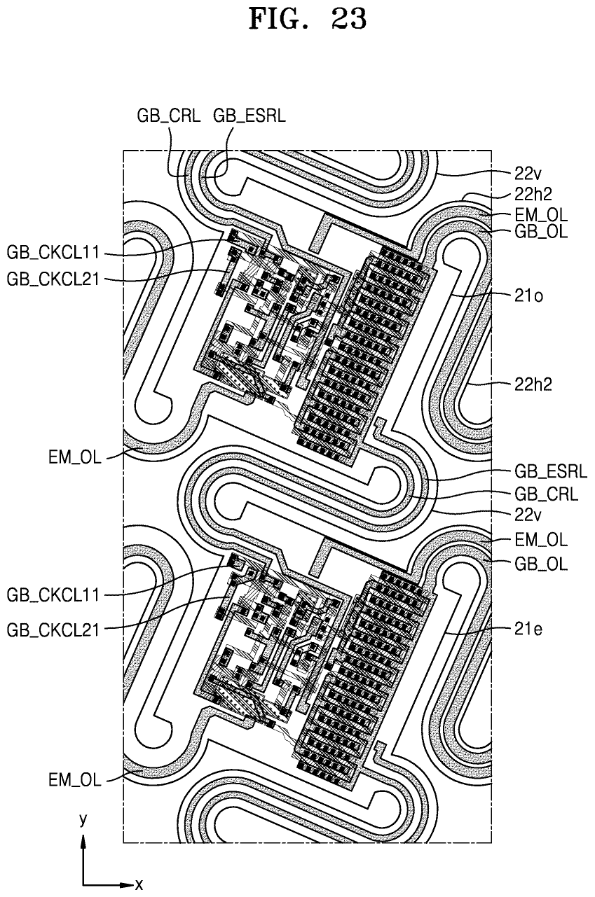

Referring to FIG. 23, a third conductive layer may be disposed on the third insulating layer 113 of the second island portion 21 and the fourth insulating layer 114 of the second bridge portion 22. The third conductive layer may include a first clock connection line GB_CKCL11, a second clock connection line GB_CKCL21, source electrodes and drain electrodes, a carry line GB_CRL configured to transmit a start signal or a previous carry signal, a reset line GB_ESRL configured to transmit a reset signal, and an output line (hereinafter, a third output line) GB_OL configured to output a third scan signal GB.

The first clock connection line GB_CKCL11 and the second clock connection line GB_CKCL21 may be arranged in the second island portion 21. In the odd-numbered second island portion 21o, the first clock connection line GB_CKCL11 may be connected to the gate electrode of the first transistor T1, and the second clock connection line GB_CKCL21 may be connected to one of the source electrode and drain electrode of the third transistor T3, the gate electrode of the sixth transistor T6, and one of the source electrode and drain electrode of the seventh transistor T7. In the even-numbered second island portion 21e, the first clock connection line GB_CKCL11 may be connected to one of the source electrode and drain electrode of the third transistor T3, the gate electrode of the sixth transistor T6, and one of the source electrode and drain electrode of the seventh transistor T7, and the second clock connection line GB_CKCL21 may be connected to the gate electrode of the first transistor T1.

The source electrodes and drain electrodes may be arranged in the second island portion 21. Each of the source electrodes may be connected to a corresponding source region of the semiconductor layer ACT, and each of the drain electrodes may be connected to a corresponding drain region of the semiconductor layer ACT.

The third output line GB_OL and the fourth output line EM_OL may be arranged apart from each other in the second horizontal bridge portion 22h2. The carry line GB_CRL and the reset line GB_ESRL may be arranged apart from each other in the vertical bridge portion 22v. The third output line GB_OL may extend from one of the source electrode and drain electrode of the ninth transistor T9 and one of the source electrode and drain electrode of the tenth transistor T10. The carry line GB_CRL may be connected to one of the source electrode and drain electrode of the first transistor T1. The reset line GB_ESRL may be connected to the gate electrode of the thirteenth transistor T13.

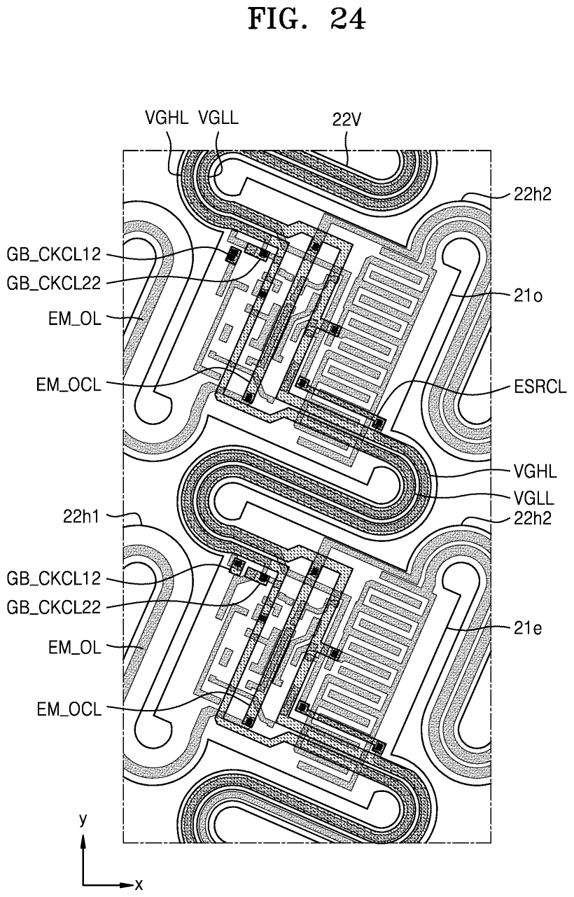

Referring to FIG. 24, a fifth insulating layer 115 (FIG. 26) may be disposed on the third insulating layer 113 of the second island portion 21 and the fourth insulating layer 114 of the second bridge portion 22 to cover the third conductive layer. Contact holes may be defined in the fifth insulating layer 115. A fourth conductive layer may be disposed on the fifth insulating layer 115. The fourth conductive layer may include a first clock connection electrode GB_CKCL12, a second clock connection electrode GB_CKCL22, a reset connection line ESRCL, an output connection line EM_OCL, a first voltage line VGHL configured to transmit a first voltage VGH, and a second voltage line VGLL configured to transmit a second voltage VGL.

The first clock connection electrode GB_CKCL12, the second clock connection electrode GB_CKCL22, the reset connection line ESRCL, and the output connection line EM_OCL may be arranged in the second island portion 21. The first clock connection electrode GB_CKCL12 may be connected to the first clock connection line GB_CKCL11, and the second clock connection electrode GB_CKCL22 may be connected to the second clock connection line GB_CKCL21. The reset connection line ESRCL may connect the reset lines GB_ESRL, which are arranged in the vertical bridge portions 22v arranged in the second direction with the second island portion 21 therebetween, to each other. The output connection line EM_OCL may connect the fourth output line EM_OL of the first horizontal bridge portion 22h1 and the fourth output line EM_OL of the second horizontal bridge portion 22h2 to each other.

The first voltage line VGHL and the second voltage line VGLL may be arranged in the vertical bridge portion 22v, and the first voltage line VGHL and the second voltage line VGLL may extend across the second island portion 21. In the second island portion 21, the first voltage line VGHL may be connected to one of the source electrode and drain electrode of the second transistor T2, one of the source electrode and drain electrode of the eighth transistor T8, one of the source electrode and drain electrode of the ninth transistor T9, one of the source electrode and drain electrode of the thirteenth transistor T13, and one electrode of the first capacitor C1. The second voltage line VGLL may be connected to one of the source electrode and drain electrode of the fifth transistor T5, one of the source electrode and drain electrode of the tenth transistor T10, the gate electrode of the twelfth transistor T12, and the gate electrode of the sixteenth transistor T16.

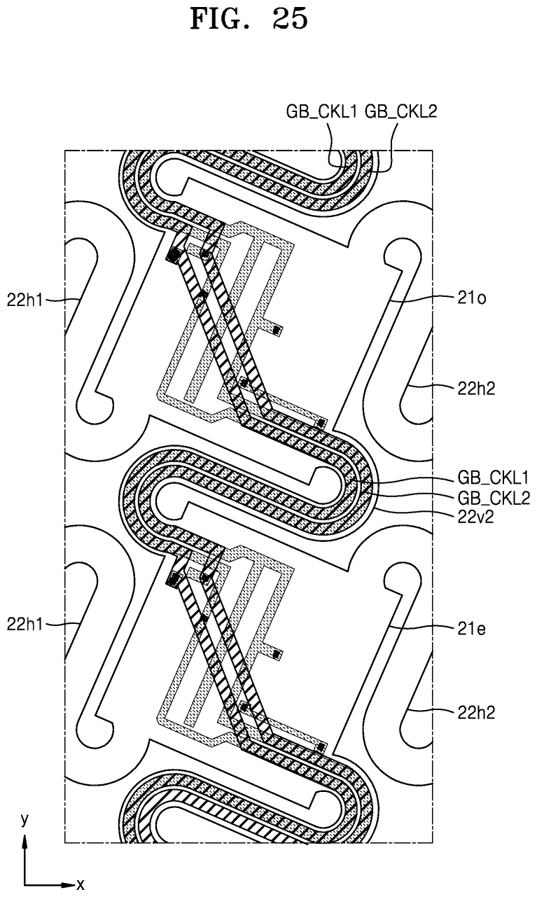

Referring to FIG. 25, a sixth insulating layer 116 (FIG. 26) may be disposed on the fifth insulating layer 115 to cover the fourth conductive layer. Contact holes may be defined in the sixth insulating layer 116. A fifth conductive layer may be disposed on the sixth insulating layer 116. The fifth conductive layer may include a first clock line GB_CKL1 and a second clock line GB_CKL2.

The first clock line GB_CKL1 and the second clock line GB_CKL2 may be arranged in the vertical bridge portion 22v. The first clock line GB_CKL1 and the second clock line GB_CKL2 may extend across the second island portion 21. In the second island portion 21, the first clock line GB_CKL1 may be connected to the first clock connection electrode GB_CKCL12, and the second clock line GB_CKL2 may be connected to the second clock connection electrode GB_CKCL22.

In the disclosure, the voltage line (e.g., the first voltage line VGHL and the second voltage line VGLL) and the clock line (e.g., first clock line GB_CKL1 and the second clock line GB_CKL2) may be also referred to as a second conductive line.

A seventh insulating layer 117 (FIG. 26) may be disposed on the sixth insulating layer 116 to cover the fifth conductive layer.

As shown in FIG. 26, in the vertical bridge portion 22v, the first voltage line VGHL may overlap the reset line GB_ESRL, and the second voltage line VGLL may overlap the carry line GB_CRL. The first clock line GB_CKL1 may overlap the second voltage line VGLL, and the second clock line GB_CKL2 may overlap the first voltage line VGHL.

FIG. 26 shows a semiconductor layer 51, a gate electrode 53, a source electrode 55, and a drain electrode 57 of the tenth transistor T10, and a lower electrode CE1 and an upper electrode CE2 of the third capacitor C3, which are arranged in the second island portion 21.

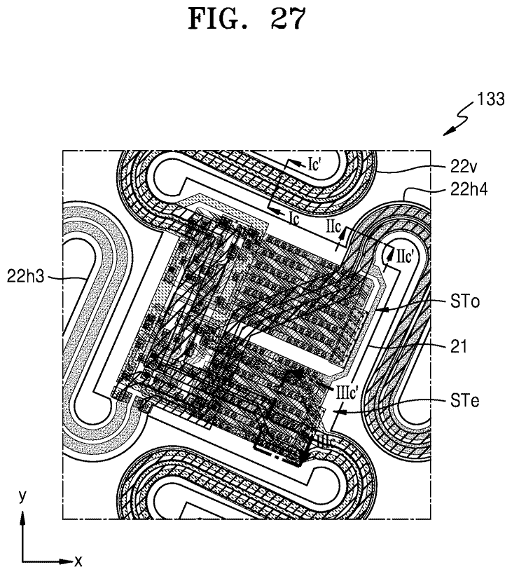

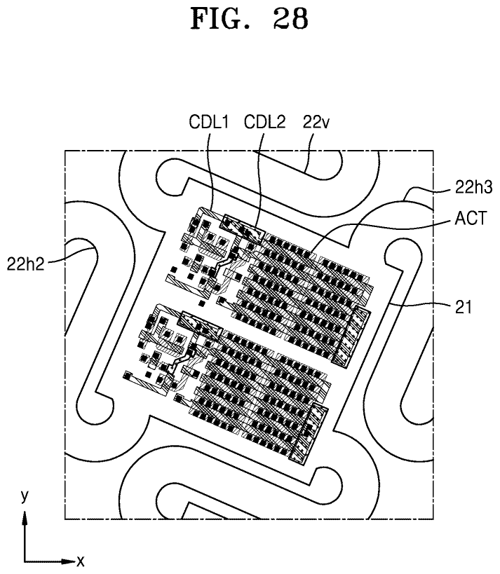

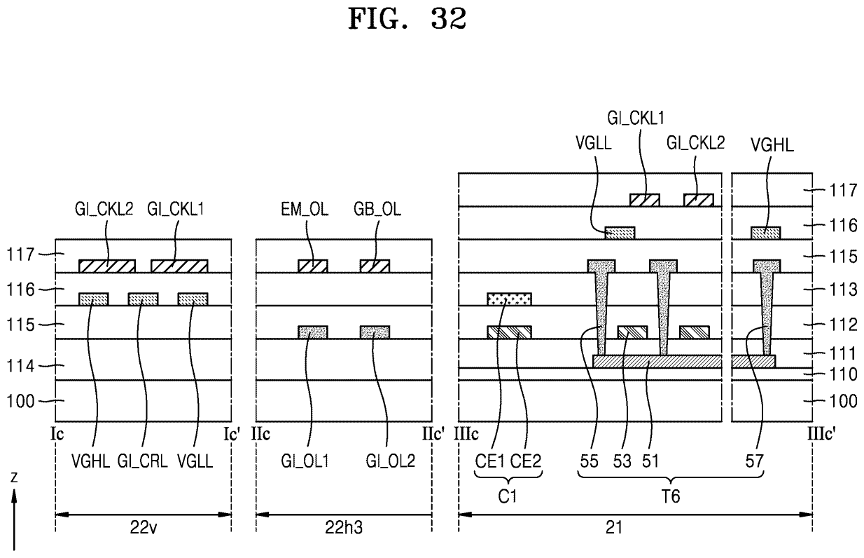

FIG. 27 is a schematic view of an embodiment of a portion of the second driving circuit 133. FIGS. 28 to 31 are schematic views of components of each layer of the second driving circuit 133 shown in FIG. 27. FIG. 32 is a cross-sectional view of the second driving circuit 133 shown in FIG. 27, taken along lines Ic-Ic′, IIc-IIc′, and IIIc-IIIc′.

The second stage of the second driving circuit 133 may be disposed in the second island portion 21 of the second column. FIG. 27 shows an odd-numbered stage STo and an even-numbered stage STe of the second driving circuit 133, which are next (adjacent) to each other in the second direction. Referring to FIG. 27, the odd-numbered stage STo and the even-numbered stage STe may be arranged next (adjacent) to each other in one second island portion 21.

Referring to FIG. 28, a semiconductor layer ACT, a first conductive layer CDL1, and a second conductive layer CDL2 may be sequentially arranged in the second island portion 21. A barrier layer 110 (FIG. 32) may be disposed between a substrate 100 (FIG. 32) and the semiconductor layer ACT. The semiconductor layer ACT may include a silicon semiconductor. The semiconductor layer ACT may include a channel region, and a source region and a drain region, which are on two sides of the channel region, of each of the first to eighth transistors T1 to T8 (FIG. 11). In some cases, the source region or the drain region may be interpreted as a source electrode or a drain electrode of a transistor.

A first insulating layer 111 (FIG. 32) may be disposed on the barrier layer 110 to cover the semiconductor layer ACT, and the first conductive layer CDL1 may be disposed on the first insulating layer 111. The first conductive layer CDL1 may include a gate electrode of each of the first to eighth transistors T1 to T8 and a lower electrode of each of the first and second capacitors C1 and C2 (FIG. 11). The gate electrodes may overlap the channel regions of the semiconductor layer ACT.

A second insulating layer 112 (FIG. 32) may be disposed on the first insulating layer 111 to cover the first conductive layer CDL1, and the second conductive layer CDL2 may be disposed on the second insulating layer 112. The second conductive layer CDL2 may include an upper electrode of each of the first and second capacitors C1 and C2. The upper electrode of each of the first and second capacitors C1 and C2 may overlap the lower electrode of each of the first and second capacitors C1 and C2.

A third insulating layer 113 (FIG. 32) may be disposed on the second insulating layer 112 to cover the second conductive layer CDL2, and contact holes may be defined in the first insulating layer 111, the second insulating layer 112, and the third insulating layer 113.

Thereafter, as described with reference to FIG. 17, areas other than the area corresponding to the second island portion 21 may be removed from the barrier layer 110, the first insulating layer 111, the second insulating layer 112, and the third insulating layer 113. A fourth insulating layer 114 may be disposed in an area other than the area corresponding to the second island portion 21 of the substrate 100.

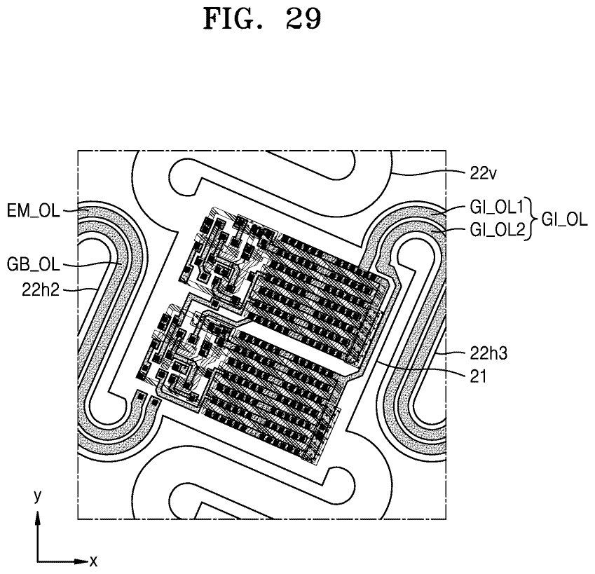

Referring to FIG. 29, a third conductive layer may be disposed on the third insulating layer 113 of the second island portion 21 and the fourth insulating layer 114 of the second bridge portion 22. The third conductive layer may include source electrodes, drain electrodes, and an output line (hereinafter, a second output line) GI_OL configured to output a second scan signal GI.

The source electrodes and drain electrodes may be arranged in the second island portion 21. Each of the source electrodes may be connected to a corresponding source region of the semiconductor layer ACT, and each of the drain electrodes may be connected to a corresponding drain region of the semiconductor layer ACT.

A second output line GI_OL1 of the odd-numbered stage STo and a second output line GI_OL2 of the even-numbered stage STe may be arranged in the third horizontal bridge portion 22h3. The second output lines GI_OL1 and GI_OL2 may extend from one of the source electrode and drain electrode of the sixth transistor T6 and one of the source electrode and drain electrode of the seventh transistor T7.

A fifth insulating layer 115 (FIG. 32) may be disposed on the third insulating layer 113 of the second island portion 21 and the fourth insulating layer 114 of the second bridge portion 22 to cover the third conductive layer. Contact holes may be defined in the fifth insulating layer 115.

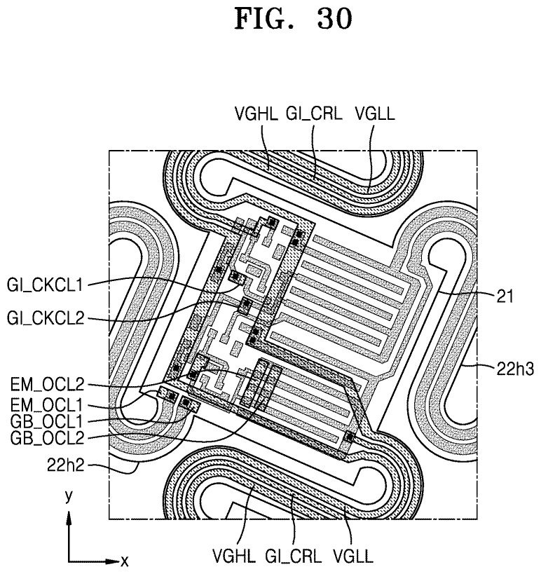

Referring to FIG. 30, a fourth conductive layer may be disposed on the fifth insulating layer 115. The fourth conductive layer may include a first clock connection electrode GI_CKCL1, a second clock connection electrode GI_CKCL2, a first connection electrode EM_OCL1, a second connection electrode EM_OCL2, a third connection electrode GB_OCL1, a fourth connection electrode GB_OCL2, a carry line GI_CRL, a first voltage line VGHL, and a second voltage line VGLL.

The first clock connection electrode GI_CKCL1, the second clock connection electrode GI_CKCL2, the first connection electrode EM_OCL1, the second connection electrode EM_OCL2, the third connection electrode GB_OCL1, and the fourth connection electrode GB_OCL2 may be arranged in the second island portion 21.

In the odd-numbered stage STo, the first clock connection electrode GI_CKCL1 may be connected to the gate electrode of the first transistor T1, one of the source electrode and drain electrode of the fourth transistor T4, and the gate electrode of the fifth transistor T5. In the even-numbered stage STe, the first clock connection electrode GI_CKCL1 may be connected to the gate electrode of the third transistor T3 and one of the source electrode and drain electrode of the seventh transistor T7. In the odd-numbered stage STo, the second clock connection electrode GI_CKCL2 may be connected to the gate electrode of the third transistor T3 and one of the source electrode and drain electrode of the seventh transistor T7. In the even-numbered stage STe, the second clock connection electrode GI_CKCL2 may be connected to the gate electrode of the first transistor T1, one of the source electrode and drain electrode of the fourth transistor T4, and the gate electrode of the fifth transistor T5.

The first connection electrode EM_OCL1 may be connected to the fourth output line EM_OL of the second horizontal bridge portion 22h2. The third connection electrode GB_OCL1 may be connected to the third output line GB_OL of the second horizontal bridge portion 22h2.

The carry line GI_CRL, the first voltage line VGHL, and the second voltage line VGLL may be arranged in the vertical bridge portion 22v. The carry line GI_CRL disposed in the vertical bridge portion 22v on the upper side may be connected to one of the source electrode and drain electrode of the first transistor T1 of the odd-numbered stage STo. The carry line GI_CRL disposed in the vertical bridge portion 22v on the lower side may be connected to the second output line GI_OL2 connected to the seventh transistor T7 of the even-numbered stage STe. The first voltage line VGHL and the second voltage line VGLL may extend across the second island portion 21. In the second island portion 21, the first voltage line VGHL may be connected to one of the source electrode and drain electrode of the second transistor T2, one of the source electrode and drain electrode of the sixth transistor T6, and one electrode of the first capacitor C1. The second voltage line VGLL may be connected to one of the source electrode and drain electrode of the fifth transistor T5 and the gate electrode of the eighth transistor T8.

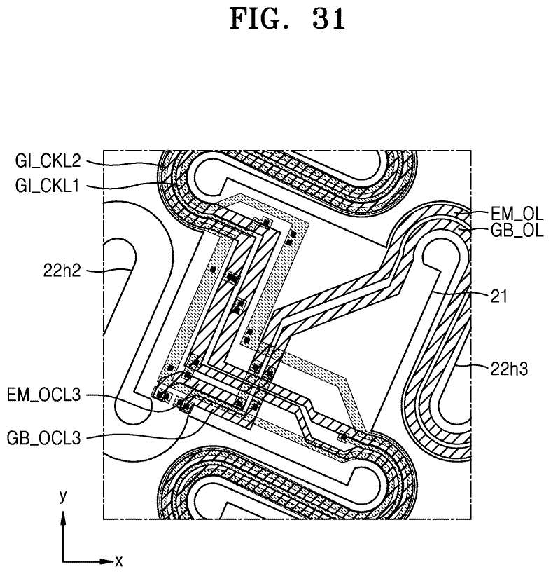

Referring to FIG. 31, a sixth insulating layer 116 (FIG. 32) may be disposed on the fifth insulating layer 115 to cover the fourth conductive layer. Contact holes may be defined in the sixth insulating layer 116. A fifth conductive layer may be disposed on the sixth insulating layer 116. The fifth conductive layer may include a first clock line GI_CKL1, a second clock line GI_CKL2, a fifth connection electrode EM_OCL3, a sixth connection electrode GB_OCL3, a fourth output line EM_OL, and a third output line GB_OL.

The fifth connection electrode EM_OCL3 and the sixth connection electrode GB_OCL3 may be arranged in the second island portion 21. The fifth connection electrode EM_OCL3 may be connected to the first connection electrode EM_OCL1 and the second connection electrode EM_OCL2. The sixth connection electrode GB_OCL3 may be connected to the third connection electrode GB_OCL1 and the fourth connection electrode GB_OCL2.

The first clock line GI_CKL1 and the second clock line GI_CKL2 may be arranged in the vertical bridge portion 22v. The first clock line GI_CKL1 and the second clock line GI_CKL2 may extend across the second island portion 21. In the second island portion 21, the first clock line GI_CKL1 may be connected to the first clock connection electrode GI_CKCL1, and the second clock line GI_CKL2 may be connected to the second clock connection electrode GI_CKCL2.

The fourth output line EM_OL and the third output line GB_OL may be arranged in the third horizontal bridge portion 22h3. The fourth output line EM_OL may extend to the second island portion 21, and may be connected to the second connection electrode EM_OCL2 in the second island portion 21. The third output line GB_OL may extend to the second island portion 21, and may be connected to the fourth connection electrode GB_OCL2 in the second island portion 21.

In the disclosure, the voltage line (e.g., the first voltage line VGHL and the second voltage line VGLL) and the clock line (e.g., first clock line GI_CKL1 and the second clock line GI_CKL2) may be also referred to as a second conductive line.

A seventh insulating layer 117 (FIG. 32) may be disposed on the sixth insulating layer 116 to cover the fifth conductive layer.

As shown in FIG. 32, in the vertical bridge portion 22v, the first clock line GI_CKL1 may overlap the second voltage line VGLL and a portion of the carry line GI_CRL, and the second clock line GI_CKL2 may overlap the first voltage line VGHL and a portion of the carry line GI_CRL. In the horizontal bridge portion 22h3, the fourth output line EM_OL may overlap the second output line GI_OL1 of the odd-numbered stage STo, and the third output line GB_OL may overlap the second output line GI_OL2 of the even-numbered stage STe.

FIG. 32 shows a semiconductor layer 51, a gate electrode 53, a source electrode 55, and a drain electrode 57 of the sixth transistor T6, and a lower electrode CE1 and an upper electrode CE2 of the first capacitor C1, which are arranged in the second island portion 21.

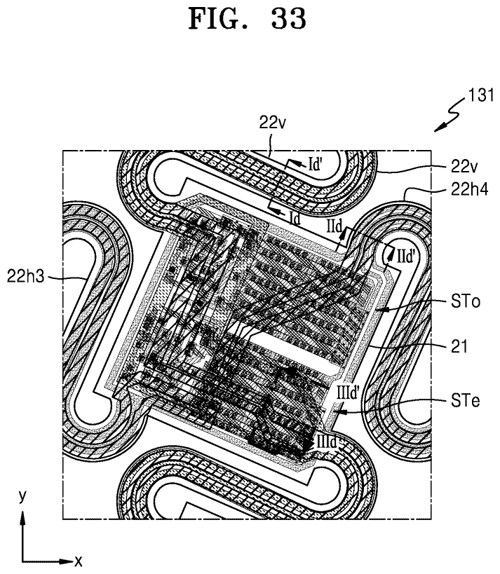

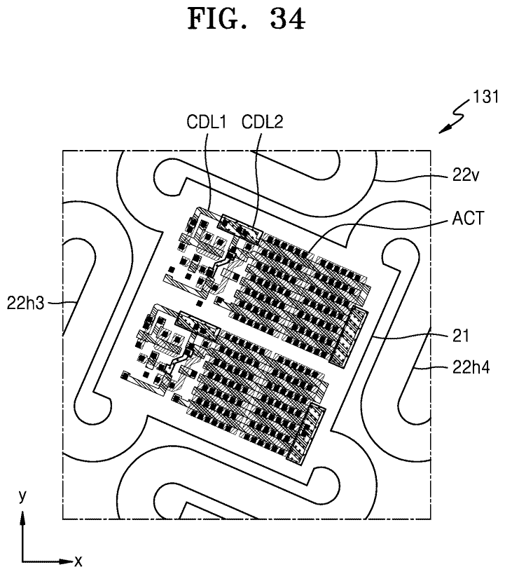

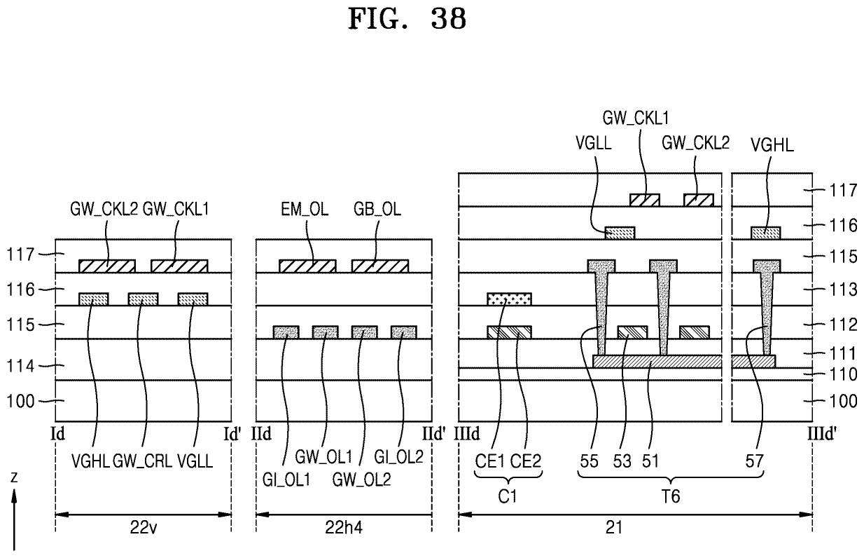

FIG. 33 is a schematic view of an embodiment of a portion of the first driving circuit 131. FIGS. 34 to 37 are schematic views of components of each layer of the first driving circuit 131 shown in FIG. 33. FIG. 38 is a cross-sectional view of the first driving circuit 131 shown in FIG. 33, taken along lines Id-Id′, IId-IId′, and IIId-IIId′.

The stage circuits of the first driving circuit 131 shown in FIG. 33 are identical to the stage circuits of the second driving circuit 133 shown in FIG. 27 except for the arrangement of output lines, and thus, differences are mainly described below.

The first stage of the first driving circuit 131 may be disposed in the second island portion 21 of the first column. FIG. 33 shows an odd-numbered stage STo and an even-numbered stage STe of the first driving circuit 131, which are next (adjacent) to each other in the second direction. Referring to FIG. 33, the odd-numbered stage STo and the even-numbered stage STe may be arranged next (adjacent) to each other in one second island portion 21.

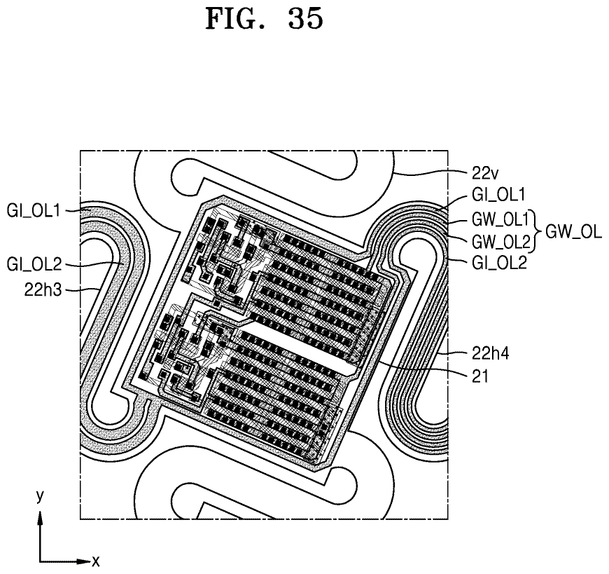

The arrangement of the first to eighth transistors T1 to T8 and the first and second capacitors C1 and C2 in the second island portion 21 shown in FIGS. 34 and 35 is identical to the arrangement of the first to eighth transistors T1 to T8 and the first and second capacitors C1 and C2 in the second island portion 21 shown in FIGS. 28 and 29.

Referring to FIG. 35, a third conductive layer may be disposed on the third insulating layer 113 (FIG. 38) of the second island portion 21 and the fourth insulating layer 114 (FIG. 38) of the second bridge portion 22. The third conductive layer may include source electrodes, drain electrodes, second output lines GI_OL1 and GI_OL2, and an output line (hereinafter, a first output line) GW_OL configured to output a first scan signal GW.

The source electrodes and drain electrodes may be arranged in the second island portion 21.

A first output line GW_OL1 of the odd-numbered stage STo and a first output line GW_OL2 of the even-numbered stage STe may be arranged apart from each other in the fourth horizontal bridge portion 22h4. The first output lines GW_OL1 and GW_OL2 may extend from one of the source electrode and drain electrode of the sixth transistor T6 and one of the source electrode and drain electrode of the seventh transistor T7.

The second output lines GI_OL1 and GI_OL2 arranged in the third horizontal bridge portion 22h3 may be arranged to extend to the second island portion 21 and the fourth horizontal bridge portion 22h4. In the second island portion 21, the second output lines GI_OL1 and GI_OL2 may respectively extend in opposite directions along an edge of the second island portion 21. The first output lines GW_OL1 and GW_OL2 and the second output lines GI_OL1 and GI_OL2 may be arranged apart from each other in the fourth horizontal bridge portion 22h4.

A fifth insulating layer 115 (FIG. 38) may be disposed on the third insulating layer 113 of the second island portion 21 and the fourth insulating layer 114 of the second bridge portion 22 to cover the third conductive layer. Contact holes may be defined in the fifth insulating layer 115.

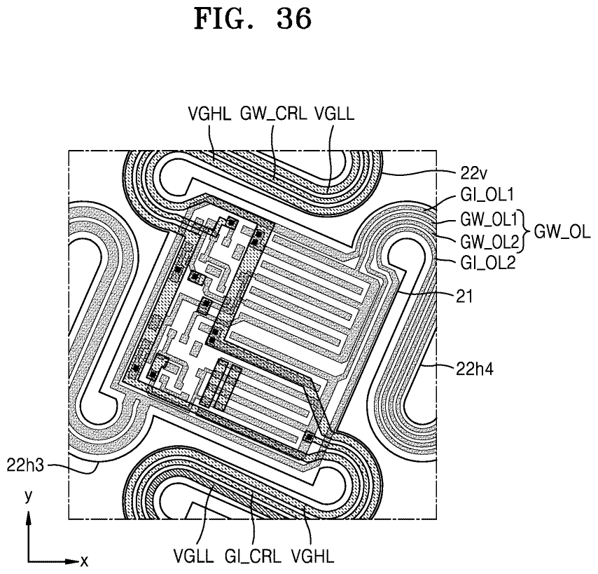

Referring to FIG. 36, a fourth conductive layer may be disposed on the fifth insulating layer 115. The fourth conductive layer may include clock connection electrodes, output connection electrodes, a carry line GW_CRL, a first voltage line VGHL, and a second voltage line VGLL.

The clock connection electrodes and output connection electrodes may be arranged in the second island portion 21. A first clock connection electrode among the clock connection electrodes may be connected to the gate electrode of the first transistor T1, one of the source electrode and drain electrode of the fourth transistor T4, the gate electrode of the fifth transistor T5 of the odd-numbered stage STo, the gate electrode of the third transistor T3, and one of the source electrode and drain electrode of the seventh transistor T7 of the even-numbered stage STe. A second clock connection electrode among the clock connection electrodes may be connected to the gate electrode of the third transistor T3 and one of the source electrode and drain electrode of the seventh transistor T7 of the odd-numbered stage STo, the gate electrode of the first transistor T1, one of the source electrode and drain electrode of the fourth transistor T4, and the gate electrode of the fifth transistor T5 of the even-numbered stage STe.

The carry line GW_CRL, the first voltage line VGHL, and the second voltage line VGLL may be arranged in the vertical bridge portion 22v. The carry line GW_CRL arranged in the vertical bridge portion 22v on the upper side may be connected to one of the source electrode and drain electrode of the first transistor T1 of the odd-numbered stage STo. The carry line GW_CRL disposed in the vertical bridge portion 22v on the lower side may be connected to the first output line GW_OL2 connected to the seventh transistor T7 of the even-numbered stage STe. The first voltage line VGHL and the second voltage line VGLL may extend across the second island portion 21. In the second island portion 21, the first voltage line VGHL may be connected to one of the source electrode and drain electrode of the second transistor T2, one of the source electrode and drain electrode of the sixth transistor T6, and one electrode of the first capacitor C1. The second voltage line VGLL may be connected to one of the source electrode and drain electrode of the fifth transistor T5 and the gate electrode of the eighth transistor T8.

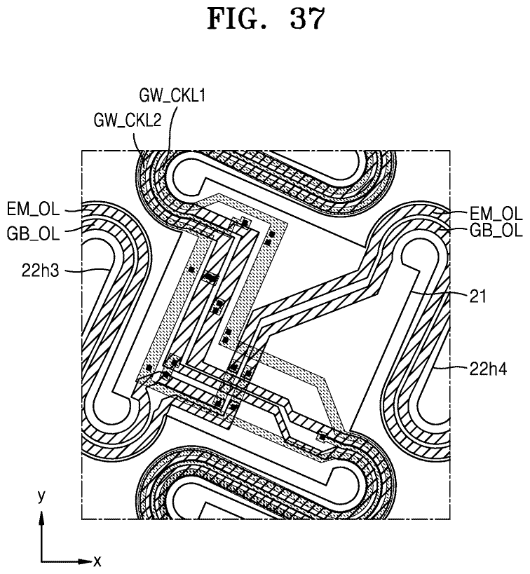

Referring to FIG. 37, a sixth insulating layer 116 (FIG. 38) may be disposed on the fifth insulating layer 115 to cover the fourth conductive layer. Contact holes may be defined in the sixth insulating layer 116. A fifth conductive layer may be disposed on the sixth insulating layer 116. The fifth conductive layer may include a first clock line GW_CKL1, a second clock line GW_CKL2, a fourth output line EM_OL, and a third output line GB_OL.

The first clock line GW_CKL1 and the second clock line GW_CKL2 may be arranged in the vertical bridge portion 22v. The first clock line GW_CKL1 and the second clock line GW_CKL2 may extend across the second island portion 21. In the second island portion 21, the first clock line GW_CKL1 may be connected to the first clock connection electrode, and the second clock line GW_CKL2 may be connected to the second clock connection electrode.

The fourth output line EM_OL and the third output line GB_OL may be arranged in the fourth horizontal bridge portion 22h4. The fourth output line EM_OL and the third output line GB_OL may extend to the second island portion 21, and may be connected to the output connection electrodes in the second island portion 21. The output connection electrodes may be connected to the fourth output line EM_OL and the third output line GB_OL arranged in the third horizontal bridge portion 22h3.

In the disclosure, the voltage line (e.g., the first voltage line VGHL and the second voltage line VGLL) and the clock line (e.g., first clock line GW_CKL1 and the second clock line GW_CKL2) may be also referred to as a second conductive line.

A seventh insulating layer 117 (FIG. 38) may be disposed on the sixth insulating layer 116 to cover the fifth conductive layer.

As shown in FIG. 38, in the vertical bridge portion 22v, the first clock line GW_CKL1 may overlap the second voltage line VGLL and a portion of the carry line GW_CRL, and the second clock line GW_CKL2 may overlap the first voltage line VGHL and a portion of the carry line GW_CRL. In the fourth horizontal bridge portion 22h4, the fourth output line EM_OL may overlap the second output line GI_OL1 of the odd-numbered stage STo and the first output line GW_OL1 of the odd-numbered stage STo, and the third output line GB_OL may overlap the second output line GI_OL2 of the even-numbered stage STe and the first output line GW_OL2 of the even-numbered stage STe.

FIG. 38 shows a semiconductor layer 51, a gate electrode 53, a source electrode 55, and a drain electrode 57 of the sixth transistor T6, and a lower electrode CE1 and an upper electrode CE2 of the first capacitor C1, which are arranged in the second island portion 21.

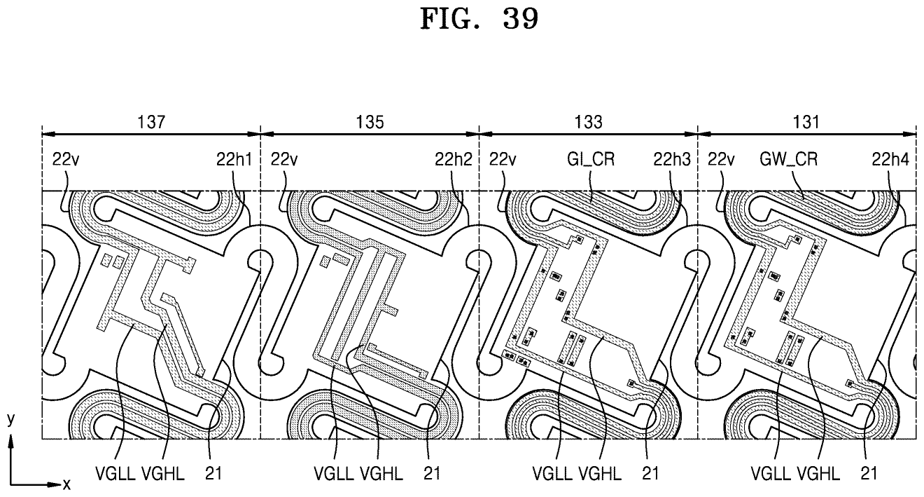

FIG. 39 is a schematic view of an embodiment of a fourth conductive layer.

Referring to FIG. 39, in each column, the first voltage line VGHL and the second voltage line VGLL may be arranged to extend to the vertical bridge portions 22v in the second direction. The first voltage line VGHL and the second voltage line VGLL may pass through the second island portions 21 extended between the vertical bridge portions 22v to overlap the stage circuit STC. Each of the first voltage line VGHL and the second voltage line VGLL may extend in the second direction across the second island portion 21 as a single conductive line, thereby minimizing resistance and coupling capacitance effects.

The first voltage line VGHL and the second voltage line VGLL may be connected to a stage circuit through contact holes in the second island portion 21, and may transmit signals to the stage circuit.

In the third driving circuit 135 and the fourth driving circuit 137, the first voltage line VGHL and the second voltage line VGLL may be arranged above a carry line and a reset line, which are formed by a third conductive layer. In the first driving circuit 131 and the second driving circuit 133, the first voltage line VGHL and the second voltage line VGLL may be arranged in the same layer as a carry line. By arranging the carry line in the same layer as the first voltage line VGHL and the second voltage line VGLL, capacitance due to overlap between conductive lines may be reduced, and the number of contact holes for connection between the conductive lines and the stage circuit in the second island portion may be reduced, thereby optimizing connection with the stage circuit.

In an embodiment, first voltages VGH transmitted by the first voltage lines VGHL connected to the first driving circuit 131, the second driving circuit 133, the third driving circuit 135, and the fourth driving circuit 137 may be identical to or different from each other. Second voltages VGL transmitted by the second voltage lines VGLL connected to the first driving circuit 131, the second driving circuit 133, the third driving circuit 135, and the fourth driving circuit 137 may be identical to or different from each other.

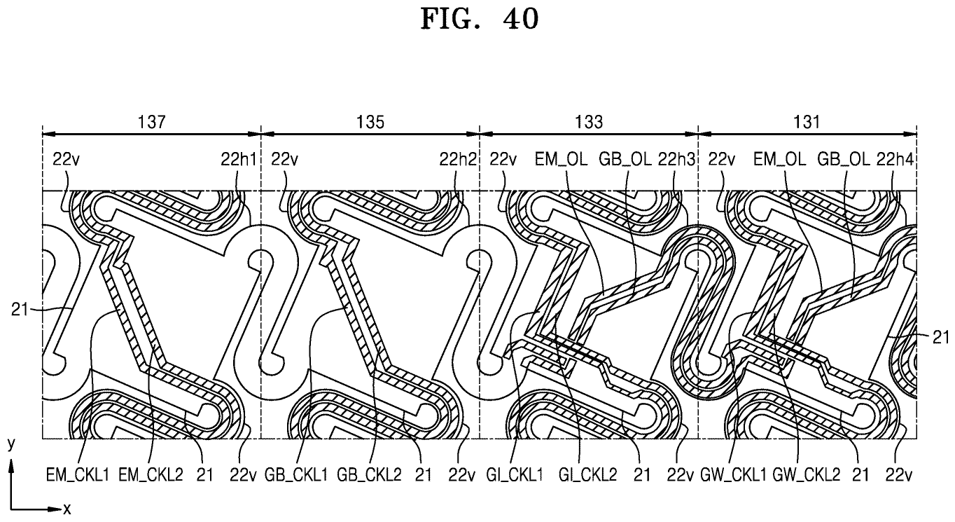

FIG. 40 is a schematic view of an embodiment of a fifth conductive layer.

Referring to FIG. 40, in each column, the first clock line EM_CKL1, GB_CKL1, GI_CKL1, or GW_CKL1 and the second clock line EM_CKL2, GB_CKL2, GI_CKL2, or GW_CKL2 may be arranged to extend to the vertical bridge portions 22v in the second direction. The first clock line EM_CKL1, GB_CKL1, GI_CKL1, or GW_CKL1 and the second clock line EM_CKL2, GB_CKL2, GI_CKL2, or GW_CKL2 may pass through the second island portions 21 extended between the vertical bridge portions 22v to overlap the stage circuit STC. The first clock line EM_CKL1, GB_CKL1, GI_CKL1, or GW_CKL1 and the second clock line EM_CKL2, GB_CKL2, GI_CKL2, or GW_CKL2 may extend in the second direction across the second island portion 21 as a single conductive line, thereby minimizing resistance.

The first clock line EM_CKL1, GB_CKL1, GI_CKL1, or GW_CKL1 and the second clock line EM_CKL2, GB_CKL2, GI_CKL2, or GW_CKL2 may be connected to a stage circuit through contact holes in the second island portion 21, and may transmit signals to the stage circuit.

In the first driving circuit 131 and the second driving circuit 133, the third output line GB_OL and the fourth output line EM_OL may be arranged in the horizontal bridge portion 22h in the first direction, in the same layer as the first clock line EM_CKL1, GB_CKL1, GI_CKL1, or GW_CKL1 and the second clock line EM_CKL2, GB_CKL2, GI_CKL2, or GW_CKL2.

A first clock signal GW_CLK1 transmitted by the first clock line GW_CKL1 and a second clock signal GW_CLK2 transmitted by the second clock line GW_CKL2 connected to the first driving circuit 131, a first clock signal GI_CLK1 transmitted by the first clock line GI_CKL1 and a second clock signal GI_CLK2 transmitted by the second clock line GI_CKL2 connected to the second driving circuit 133, a first clock signal GB_CLK1 transmitted by the first clock line GB_CKL1 and a second clock signal GB_CLK2 transmitted by the second clock line GB_CKL2 connected to the third driving circuit 135, and a first clock signal EM_CLK1 transmitted by the first clock line EM_CKL1 and a second clock signal EM_CLK2 transmitted by the second clock line EM_CKL2 connected to the fourth driving circuit 137 may be identical to each other, or at least one thereof may be different.

In the disclosure, a carry line (e.g., carry line GB_CRL) connected to stages of the second driving circuit 133 may be also referred to as a first carry line, and a carry line (e.g., carry line GI_CRL) connected to stages of the third driving circuit 135 may be also referred to as a second carry line, the first voltage line VGHL, the second voltage line VGLL, the first and second clock lines (e.g., GB_CKL1 and GB_CKL2) and the first carry line connected to stages of the second driving circuit 133 may be referred to as a first vertical conductive line, and the first voltage line VGHL, the second voltage line VGLL, the first and second clock lines (e.g., GI_CKL1 and GI_CKL2) and the second carry line may be also referred to as a second vertical conductive line.

In a display panel in embodiments of the disclosure, island portions and bridge portions may be defined in a display area and a non-display area, and sides of the island portions may be arranged to be inclined at a predetermined angle, so that a display device with a relatively high elongation and relatively high resolution may be implemented. In the display panel in embodiments of the disclosure, in the non-display area, signal lines connected to a stage circuit may be arranged to overlap the stage circuit across island portions in which the stage circuit is disposed, instead of being arranged in an island portion that is separately disposed around an island portion in which the stage circuit is disposed. Accordingly, the size of the non-display area may be reduced. In the display panel in embodiments of the disclosure, the signal lines connected to the stage circuit may be formed as a single conductive line (e.g., a voltage line formed by a fourth conductive layer, or a clock line formed by a fifth conductive layer) to reduce the resistance of the conductive line and minimize coupling capacitance, thereby minimizing the load on the display panel.

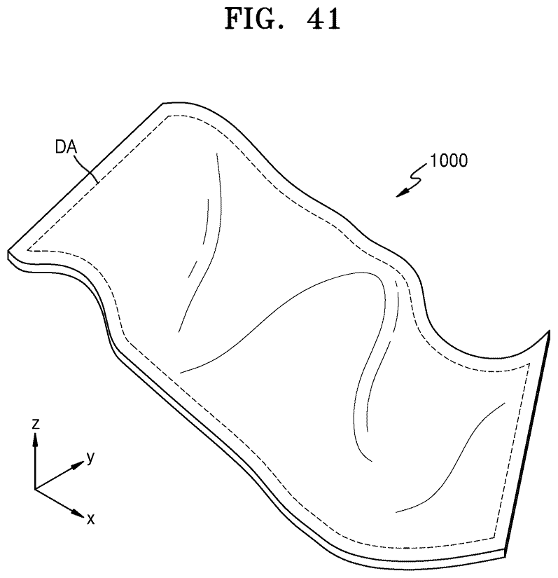

FIG. 41 is a schematic perspective view of an embodiment of an electronic device including a display panel.

Referring to FIG. 41, an electronic device 1000 may be freely transformed in three dimensions, and may provide a three-dimensional image surface through a display area DA. The electronic device 1000 being freely transformed in three dimensions is distinguished from an operation of an electronic device having a rollable display panel, such as the case where a rolled up portion of a display area is visible to a user, and then, as another rolled up portion of the display area is unfolded, the entirety of the display area becomes visible to the user (or the case where the entirety of the unfolded display area is visible to a user, and then, as the display area is rolled up, only a portion of the display area becomes visible to the user). The electronic device 1000 in embodiments of the disclosure may exhibit deformation, e.g., the area of the entirety of the display area DA may increase or decrease as the electronic device 1000 is deformed in the x-direction, the y-direction, and/or the z-direction.

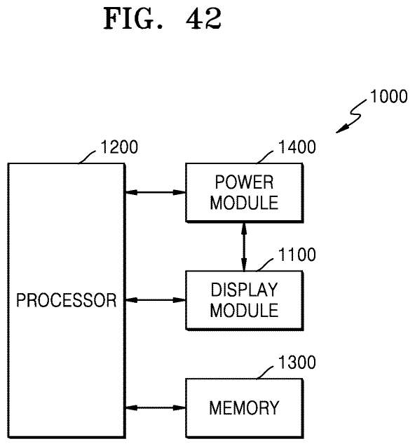

### Fig. 42 Is a Block Diagram of an Embodiment of an Electronic Device.

Referring to FIG. 42, the electronic device 1000 in an embodiment may include a display module 1100, a processor 1200, a memory 1300, and a power module 1400.

The electronic device 1000 may output various information through the display module 1100 within an operating system.

The processor 1200 may include at least one of a central processing unit (“CPU”), an application processor (“AP”), a graphic processing unit (“GPU”), a communication processor (“CP”), an image signal processor (“ISP”), and a controller. In an embodiment, the processor 1200 may be divided into two or more processors from a functional or structural perspective. In an embodiment, the processor 1200 may include a main processor in the form of a first driving chip including a CPU, and an auxiliary processor in the form of a second driving chip including a controller that receives an image signal from the main processor and processes the image signal to match interface specifications of the display module 1100.

The memory 1300 may include at least one of non-volatile memory and volatile memory. The memory 1300 may store data information desired for an operation of the processor 1200 or the display module 1100. When the processor 1200 executes an application stored in the memory 1300, an image data signal and/or an input control signal may be transmitted to the display module 1100, and the display module 1100 may process the received signal and output image information through a display screen.

The power module 1400 may include a power supply module, such as a power adapter or a battery device, and a power conversion module that converts power supplied by the power supply module to generate power desired for an operation of the electronic device 1000. Power conversion by the power conversion module may include direct current to direct current (“DC-DC”) conversion, alternating current to direct current (“AC-DC”) conversion, and direct current to alternating current (“DC-AC”) conversion, but is not limited thereto.

At least one of the components of the electronic device 1000 described above may be included in a display device in the embodiments described above. Also, some of individual modules functionally included in one module may be included in the display device, and others may be provided separately from the display device. In an embodiment, the display device may include the display module 1100 and the auxiliary processor of the processor 1200, and the main processor of the processor 1200, the memory 1300, and the power module 1400 may be provided in the form of other devices in the electronic device 1000 other than the display device. In another embodiment, the power module 1400 may be provided in the display device and supply power to the processor 1200 and the memory 1300, which are provided in the electronic device 1000 other than the display device, but is not limited to the above example.

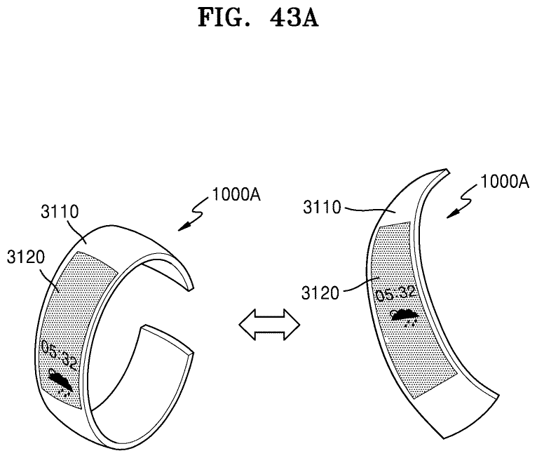

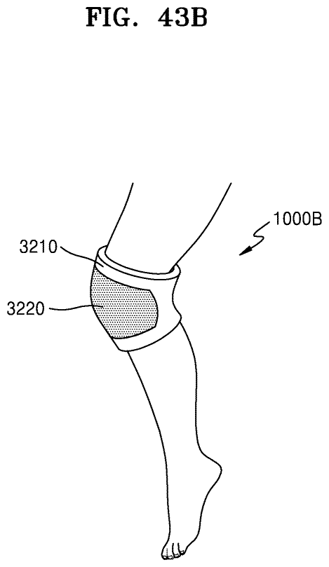

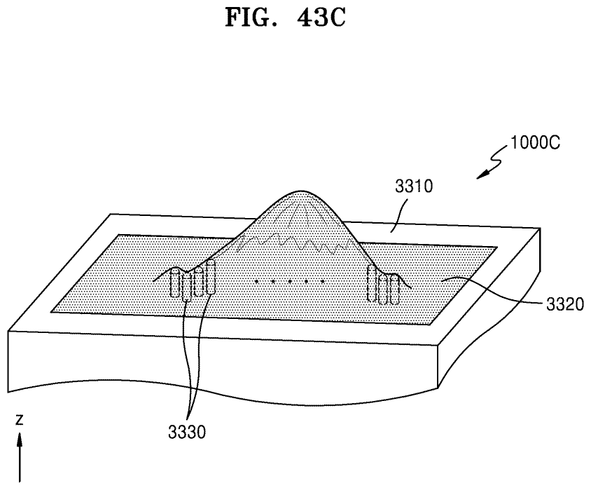

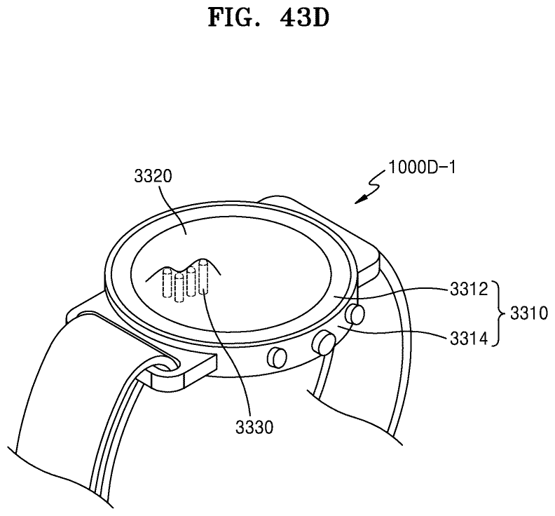

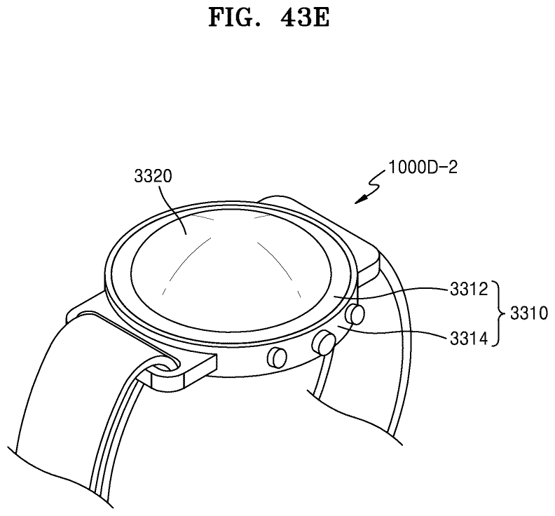

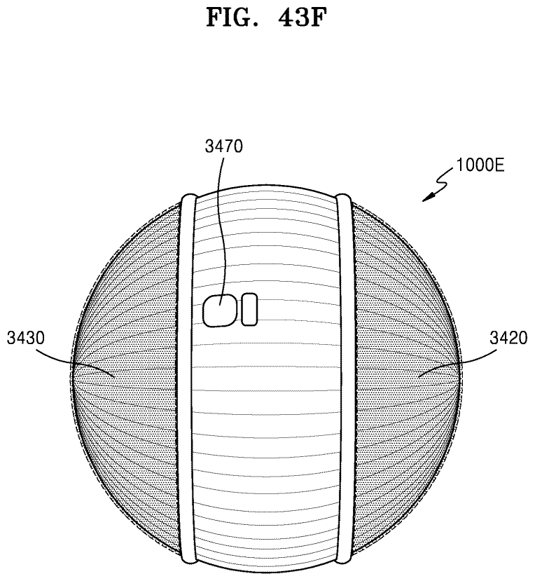

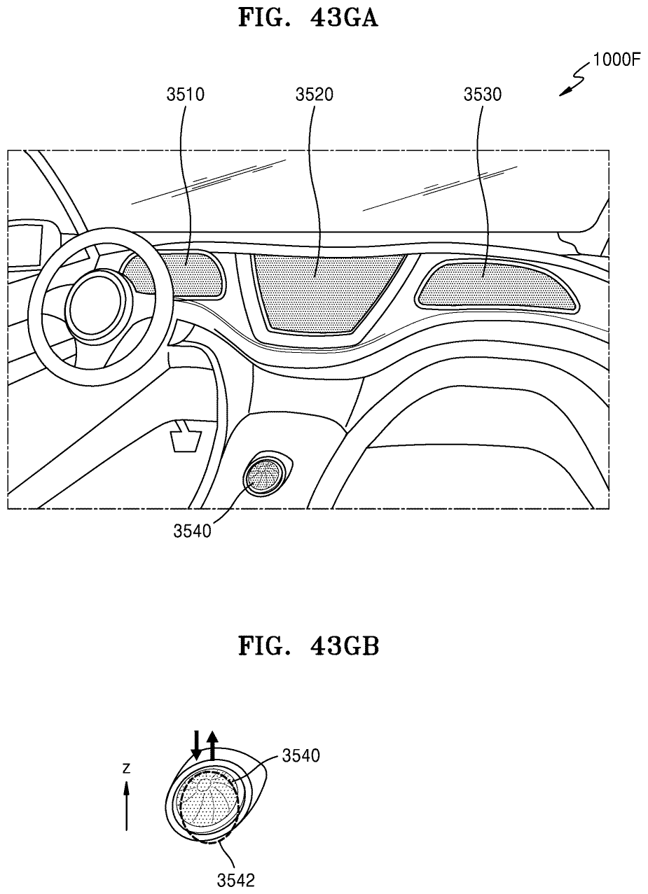

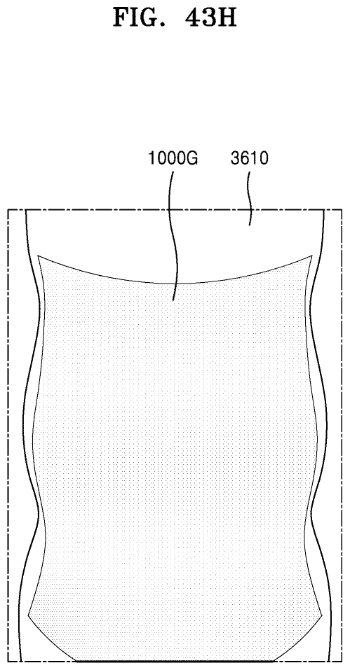

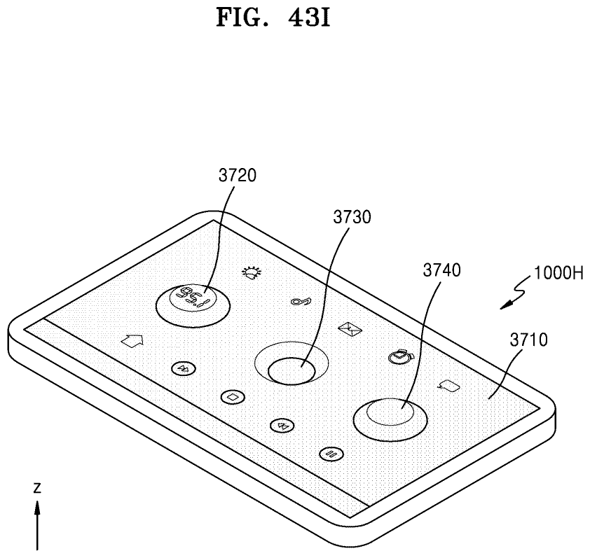

FIGS. 43A to 43I are schematic perspective views of embodiments of an electronic device including a display panel, according to the disclosure.

Referring to FIG. 43A, the display panel in an embodiment of the disclosure may be used in a wearable electronic device 1000A that may be worn on a part of a user's body. The wearable electronic device 1000A may include a body portion 3110 and a display 3120 provided on the body portion 3110. The display panel in embodiments of the disclosure may be used as the display 3120 of the wearable electronic device 1000A. As shown in FIG. 43A, the wearable electronic device 1000A may be deformable. In an embodiment, the wearable electronic device 1000A may be used as a smart watch or a smartphone according to the user's choice.

FIG. 43B shows a medical electronic device 1000B. In an embodiment, the medical electronic device 1000B may include a body portion 3210 and an emission portion 3220. The display panel in embodiments of the disclosure may be used as the emission portion 3220 of the medical electronic device 1000B. The emission portion 3220 may emit light of a predetermined wavelength band (e.g., infrared light, visible light, etc.) to a patient's body. In an embodiment, the body portion 3210 may include a stretchable fiber material, and may have a structure that may be worn on a user's body.

FIG. 43C shows an educational electronic device 1000C. In an embodiment, the educational electronic device may include a display 3320 provided within a housing 3310. The display 3320 may use the display panel according to the disclosure. The display 3320 may provide an image of a sea with waves, a mountain covered in snow, or a volcano with flowing lava, and in this case, the display 3320 may be stretched in a height direction (e.g., the z-direction) to reflect the height of the waves, the mountain, or the volcano. In some embodiments, the height of a portion of the display 3320 may sequentially vary in a direction in which the lava flows, thereby displaying movement of the lava in three dimensions. The educational electronic device 1000C may include a plurality of pins (or stroke portions) 3330 arranged on a rear surface of the display 3320 so that the display 3320 is stretched in the height direction. As the pins 3330 move in the third direction (e.g., the z-direction or the −z-direction), an image expressed on the display 3320 may be implemented to have a three-dimensional height. While FIG. 43C illustrates the educational electronic device 1000C, the use thereof is not limited as long as it provides predetermined image information.

FIGS. 43D and 43E show display panels used in wearable electronic devices 1000D-1 and 1000D-2, such as smart watches.

In an embodiment, as shown in FIG. 43D, a display panel corresponding to a display 3320 of the electronic device 1000D-1 may be three-dimensionally stretched, and thus may provide a user with various haptic information, in addition to visual information through an image. In an embodiment, the electronic device 1000D-1 may provide haptic information, such as Braille markings for the visually impaired or tactile stimulation linked to an image, by a plurality of pins (or stroke portions) 3330 arranged below the display 3320. The display panel forming the display 3320 may be three-dimensionally stretched, and thus may provide the above-described haptic information to the user. The electronic device 1000D-1 may include a body portion 3310 including a housing 3314 accommodating the display panel forming the display 3320 and the pins (or stroke portions) 3330, and a frame 3312 that may be coupled to the housing 3314 with the display panel therebetween. In some embodiments, the frame 3312 may be formed as a single body with the housing 3314.

The electronic device 1000D-2 of FIG. 43E may include a body portion 3310 and a display 3320 that is accommodated in the body portion 3310 and capable of providing visual information, as shown in FIG. 43D. In some embodiments, the display panel corresponding to the display 3320 may be three-dimensionally stretched, and thus, the electronic device 1000D-2 may include a display 3320 having a dome shape. In an embodiment, in the manufacturing process of the electronic device 1000D-2, the display panel may be assembled on a dome-shaped body frame, and in this case, the display panel may be three-dimensionally stretched, and thus may be assembled in a stretched state along the shape of a hemispherical body frame.

FIG. 43F shows an embodiment of an electronic device 1000E including a robot, according to the disclosure. The robot may recognize a movement or an object by a camera module 3470, and may display a predetermined image to a user through displays 3420 and 3430.

In some embodiments, display panels in an embodiment of the disclosure may be stretched in various directions as described above, and thus may be assembled on a body frame having a hemispherical shape, and accordingly, the robot may include displays 3420 and 3430 having a hemispherical shape.

FIG. 43GA shows an embodiment of a vehicle display device 1000F as an electronic device according to the disclosure, and FIG. 43GB is an enlarged view of a portion of FIG. 43GA. The vehicle display device 1000F may include a cluster 3510, a center information display (“CID”) 3520, and/or a co-driver display 3530. A display panel in an embodiment of the disclosure may be stretched in various directions, and thus may be used in the cluster 3510, the CID 3520, and/or the co-driver display 3530, regardless of the shape of an internal frame of a vehicle.

FIG. 43GA shows that the cluster 3510, the CID 3520, and/or the co-driver display 3530 are separated from each other, but the disclosure is not limited thereto. In another embodiment, two or more selected from the cluster 3510, the CID 3520, and the co-driver display 3530 may extend into a single body.

In some embodiments, the vehicle display device 1000F may include a button 3540 capable of expressing a predetermined image. Referring to the enlarged view of FIG. 43GB, the button 3540 having a hemispherical shape may include an object 3542 that provides a feeling of use of the button 3540 while moving in the z-direction or the −z-direction, and a display panel disposed on the object 3542. In some embodiments, when the object 3542 has a three-dimensionally round surface, the display panel may also have a three-dimensionally round surface.

FIG. 43H shows an embodiment of an electronic device 1000G for advertising or exhibition as an electronic device according to the disclosure. In some embodiments, the electronic device 1000G for advertising or exhibition may be installed on a structure 3610 that is fixed, such as a wall or a pillar. When the structure 3610 includes an uneven surface as shown in FIG. 43H, the electronic device 1000G for advertising or exhibition may be disposed along the uneven surface of the structure 3610. In some embodiments, the electronic device 1000G for advertising or exhibition may be installed on the structure 3610 by a heat-shrink film, etc.

FIG. 43I shows an embodiment of a controller as an electronic device 1000H according to the disclosure. The controller may include an image-type button. In an embodiment, the controller may include first to third button areas 3720, 3730, and 3740 in which portions of a display 3710 protrude in the z-direction or protrude in the −z-direction (or are recessed in the z-direction). In some embodiments, the first and third button areas 3720 and 3740 may protrude in the z-direction, and the second button area 3730 may protrude in the −z-direction (or be recessed in the z-direction).

As such, the disclosure has been described with reference to an embodiment illustrated in the drawings, but this is merely one of embodiments, and those of ordinary skill in the art will understand that various modifications and variations of the embodiment are possible therefrom. Therefore, the true technical protection scope of the disclosure should be determined by the technical spirit of the appended claims.

What is claimed is:

1. A display panel comprising a display area and a non-display area outside of the display area, the display panel comprising:
a driving circuit including a plurality of stages in the non-display area; and
a signal line connected to the plurality of stages,
wherein the non-display area including:
a plurality of island portions; and
a plurality of bridge portions extending to the plurality of island portions, the plurality of bridge portions including:
first directional bridge portions extending in a first direction; and
second directional bridge portions extending in a second direction perpendicular to the first direction, and
wherein the plurality of stages are disposed in the plurality of island portions disposed in the second direction, and
whereinthe signal line is disposed in the plurality of bridge portions, the signal line including:
a first conductive line disposed in the first directional bridge portions; and
a second conductive line disposed in the second directional bridge portions, and
wherein the second conductive line extends across the plurality of island portions disposed in the second direction.

2. The display panel of claim 1, wherein the first conductive line includes an output line configured to output an output signal of the stage.

3. The display panel of claim 1, wherein the second conductive line includes a voltage line and a clock line, the voltage line being configured to transmit a voltage to the stage, and the clock line being configured to transmit a clock signal to the stage.

4. The display panel of claim 3, wherein the voltage line and the clock line are arranged in different layers.

5. The display panel of claim 1, wherein one of the plurality of stages is disposed in each of the plurality of island portions.

6. The display panel of claim 1, wherein an odd-numbered stage and an even-numbered stage of the plurality of stages are arranged in each of the plurality of island portions.

7. A display panel comprising a display area and a non-display area outside of the display area, the display panel comprising:
a first driving circuit including a plurality of first stages in the non-display area;
a second driving circuit including a plurality of second stages in the non-display area a first signal line connected to the plurality of first stages; and
a second signal line connected to the plurality of second stages,
wherein the non-display area including:
a plurality of island portions including:
first island portions of a first column in which the plurality of first stages are arranged; and
second island portions of a second column in which the plurality of second stages are arranged;
a plurality of bridge portions extending to the plurality of island portions, the plurality of bridge portions including:
first area bridge portions including:
first horizontal bridge portions extending in a first direction; and
first vertical bridge portions extending in a second direction perpendicular to the first direction; and
second area bridge portions including:
second horizontal bridge portions extending in the first direction; and
second vertical bridge portions extending in the second direction,
wherein the first driving circuit is closer to the display area than the second driving circuit is to the display area, and
wherein the first signal line is disposed in the first area bridge portions, the first signal line including:
a first horizontal conductive line disposed in the first horizontal bridge portions; and
a first vertical conductive line disposed in the first vertical bridge portions;
wherein the second signal line is disposed in the second area bridge portions, the second signal line including:
a second horizontal conductive line disposed in the second horizontal bridge portions; and
a second vertical conductive line disposed in the second vertical bridge portions;
the first vertical conductive line extends across the first island portions, and the second vertical conductive line extends across the second island portions.

8. The display panel of claim 7, wherein one of the plurality of first stages is disposed in each of the first island portions, and
an odd-numbered second stage and an even-numbered second stage of the plurality of second stages are arranged in each of the second island portions.

9. The display panel of claim 8, wherein the first horizontal conductive line includes a first output line configured to output an output signal of the one of the plurality of first stages, and
the second horizontal conductive line includes a second output line and a third output line, the second output line being configured to output an output signal of the odd-numbered second stage, and the third output line being configured to output an output signal of the even-numbered second stage.

10. The display panel of claim 9, wherein each of the first horizontal bridge portions extends to one of the first island portions and one of the second island portions, which are arranged in a same row.

11. The display panel of claim 10, wherein the first output line is disposed in a first horizontal bridge portion and a second horizontal bridge portion, the first horizontal bridge portion being disposed in a first row, and the second horizontal bridge portion being disposed in the first row and extending to a second island portion therein,
the second output line and the third output line are arranged apart from each other in the second horizontal bridge portion disposed in the first row, and
in the second horizontal bridge portion disposed in the first row, the first output line at least partially overlaps the second output line and the third output line in a plan view.

12. The display panel of claim 11, wherein a connection electrode is disposed in the second island portion disposed in the first row, and
the connection electrode connects the first output line disposed in the first horizontal bridge portion disposed in the first row to the first output line disposed in the second horizontal bridge portion disposed in the first row.

13. The display panel of claim 12, wherein the first output line disposed in the first horizontal bridge portion disposed in the first row and the first output line disposed in the second horizontal bridge portion disposed in the first row are arranged in different layers.

14. The display panel of claim 8, wherein the first vertical conductive line includes a first voltage line and a first clock line, the first voltage line being configured to transmit a voltage to one of the plurality of first stages, and the first clock line being configured to transmit a clock signal to the one of the plurality of first stages, and
the second vertical conductive line includes a second voltage line and a second clock line, the second voltage line being configured to transmit a voltage to the odd-numbered second stage and the even-numbered second stage, and the second clock line being configured to transmit a clock signal to the odd-numbered second stage and the even-numbered second stage.

15. The display panel of claim 14, wherein the first voltage line and the first clock line are arranged in different layers,
the second voltage line is disposed in a same layer as the first voltage line, and
the second clock line is disposed in a same layer as the first clock line.

16. The display panel of claim 15, wherein the first vertical conductive line further includes a first carry line configured to transmit a start signal to the one of the plurality of first stages, and
the second vertical conductive line further includes a second carry line configured to transmit a start signal to the odd-numbered second stage.

17. The display panel of claim 15, wherein the first carry line is disposed in a different layer from the first voltage line, and the first voltage line overlaps the first carry line, and
the second carry line is disposed in a same layer as the second voltage line.

18. An electronic device comprising:
a display panel including:
a display area including a plurality of pixels; and
a non-display area outside the display area,
a driving circuit configured to output a gate signal to the plurality of pixels of the display panel, the driving circuit including:
a first driving circuit including a plurality of first stages; and
a second driving circuit including a plurality of second stages;
a first signal line connected to the plurality of first stages; and
a second signal line connected to the plurality of second stages,
wherein the non-display area including:
a plurality of island portions including:
first island portions of a first column in which the plurality of first stages are disposed; and
second island portions of a second column in which the plurality of second stages are disposed; and
a plurality of bridge portions extending to the plurality of island portions, the plurality of bridge portions including:
first area bridge portions including:
first horizontal bridge portions extending in a first direction; and
first vertical bridge portions extending in a second direction perpendicular to the first direction; and
second area bridge portions including:
second horizontal bridge portions extending in the first direction; and
second vertical bridge portions extending in the second direction;
wherein the first signal line is disposed in the first area bridge portions, the first signal line including:
a first horizontal conductive line disposed in the first horizontal bridge portions; and
a first vertical conductive line disposed in the first vertical bridge portions; and
wherein the second signal line is disposed in the second area bridge portions, the second signal line including:
a second horizontal conductive line disposed in the second horizontal bridge portions; and
a second vertical conductive line disposed in the second vertical bridge portions,
wherein the first driving circuit is closer to the display area than the second driving circuit is to the display area, and
the first vertical conductive line extends across the first island portions, and the second vertical conductive line extends across the second island portions.

19. The electronic device of claim 18, wherein one of the plurality of first stages is disposed in each of the first island portions, and
an odd-numbered second stage and an even-numbered second stage one of the plurality of second stages are arranged in each of the second island portions.

20. The electronic device of claim 19, wherein the first vertical conductive line includes a first voltage line, a first clock line, and a first carry line, the first voltage line being configured to transmit a voltage to one of the plurality of first stages, the first clock line being configured to transmit a clock signal to one of the plurality of first stages, and the first carry line being configured to transmit a start signal to one of the plurality of first stages,
the second vertical conductive line includes a second voltage line, a second clock line, and a second carry line, the second voltage line being configured to transmit a voltage to the odd-numbered second stage and the even-numbered second stage, the second clock line being configured to transmit a clock signal to the odd-numbered second stage and the even-numbered second stage, and the second carry line being configured to transmit a start signal to the odd-numbered second stage,
the first voltage line and the first clock line are arranged in different layers,
the second voltage line is disposed in a same layer as the first voltage line,
the second clock line is disposed in a same layer as the first clock line,
the first carry line is disposed in a different layer from the first voltage line, and
the second carry line is disposed in a same layer as the second voltage line.
